(19) United States
(12) Patent Application Publication
(10) Pub. No.: US 2026/0282310 A1
(43) Pub. Date: Sep. 17, 2026

(54) SRAM UNIT, METHOD FOR MANUFACTURING SRAM UNIT, COMPLEMENTARY FIELD EFFECT TRANSISTOR, METHOD FOR MANUFACTURING COMPLEMENTARY FIELD EFFECT TRANSISTOR, STATIC RANDOM ACCESS MEMORY

(71) Applicant: INSTITUTE OF MICROELECTRONICS, CHINESE ACADEMY OF SCIENCES, Beijing (CN)

(72) Inventors: Huaxiang Yin, Beijing (CN); Lei Cao, Beijing (CN); Qingkun Li, Beijing (CN); Qingzhu Zhang, Beijing (CN)

(21) Appl. No.: 19/360,408

(22) Filed: Oct. 16, 2025

(30) Foreign Application Priority Data
Sep. 14, 2024 (CN) 202411296684.4
Mar. 12, 2025 (CN) 202510293326.6

(51) Int. Cl. H10B 10/00; G11C 11/412; H01L 23/528; H10D 30/00; H10D 30/01; H10D 30/43; H10D 62/10

(52) U.S. Cl. CPC H10B 10/12; G11C 11/412; H10D 30/014; H10D 30/0191; H10D 30/43; H10D 30/502; H10D 62/121; H10W 20/427; H10W 20/43; H10W 20/435

(57) ABSTRACT

An SRAM unit, a method for manufacturing an SRAM unit, a complementary field-effect transistor, a method for manufacturing a complementary field-effect transistor, and a static random-access memory are provided according to the present disclosure. The SRAM unit includes: a substrate, and a first complementary field-effect transistor (CFET), a second CFET, a third CFET and a fourth CFET located on the substrate. The first CFET, the second CFET, the third CFET and the fourth CFET each includes an upper transistor and a lower transistor. A conductivity type of the upper transistor is N-type, and a conductivity type of the lower transistor is P-type. The upper transistors of the third CFET and the fourth CFET serve as gate transistors. In one SRAM unit, only one buried power line is included in the substrate.

### CROSS-REFERENCE TO RELATED APPLICATIONS

The present application claims the priority to Chinese Patent Application No. 202510293326.6, filed on Mar. 12, 2025 with the China National Intellectual Property Administration, and the priority to Chinese Patent Application No.202411296684.4, filed on Sep. 14, 2024 with the China National Intellectual Property Administration, both of which are incorporated herein by reference in their entireties.

### FIELD

The present disclosure relates to the field of semiconductors, and in particular to a static random-access memory (SRAM), a method for manufacturing an SRAM unit, a complementary field-effect transistor, a method for manufacturing a complementary field-effect transistor, and a static random-access memory.

### BACKGROUND

With the development of semiconductor technologies, the feature size of integrated circuits continues to shrink. Traditional triple-gate or double-gate fin field-effect transistors (FinFET) face limitations below 3-nanometers (nm) technology nodes, and thus nanosheet-gate all round fin field-effect transistors (Nanosheet-GAAFET) that are not limited by a 3-nm technology node are developed. Further, complementary field-effect transistors (CFET) have received extensive attention and research for being able to break a 1-nm node limitation.

In the conventional technology, a memory unit of a static random-access memory (SRAM) may be formed by complementary field-effect transistors, greatly reducing the area of the static random-access memory. Referring to FIG. 1, FIG. 1 is a schematic circuit diagram of a memory unit in a static random-access memory. Referring to FIG. 2 and FIG. 3, FIG. 2 and FIG. 3 are two schematic structural diagrams of a memory unit in a static random-access memory. By configuring the memory unit with complementary field-effect transistors instead of planar transistors, the length of the memory unit is shortened from 240 nm to 76 nm, and the area of the memory unit in the static random-access memory is greatly reduced.

However, a requirement for a smaller area of the memory unit in the static random-access memory still exists.

### SUMMARY

In view of this, an object of the present disclosure is to provide a static random-access memory (SRAM) unit, a method for manufacturing an SRAM unit, a complementary field-effect transistor, a method for manufacturing a complementary field-effect transistor, and a static random-access memory. According to the present disclosure, no buried ground line is provided in a static random-access memory, the wiring space is reduced, and thus the area of a memory unit in the static random-access memory is reduced.

An SRAM unit is provided according to the present disclosure. The SRAM unit includes:
a substrate; and
a first complementary field-effect transistor (CFET), a second CFET, a third CFET and a fourth CFET located on the substrate,
where the first CFET, the second CFET, the third CFET and the fourth CFET each includes an upper transistor and a lower transistor, a conduction type of the upper transistor is N-type, a conduction type of the lower transistor is P-type, and the upper transistors of the third CFET and the fourth CFET serve as gate transistors; and
where in the SRAM unit, only one buried power line is included in the substrate.

In an embodiment, the one buried power line is connected to a power supply.

In an embodiment, a depth of the buried power line ranges from 5 nm to 1000 nm.

In an embodiment, the first CFET, the second CFET, the third CFET and the fourth CFET each includes:
a top source, a top drain, a top channel structure, a bottom source, a bottom drain and a bottom channel structure disposed on a side of the substrate; where in a direction perpendicular to a plane where the substrate is located, the top source and the bottom source overlap with each other, the top drain and the bottom drain overlap with each other, and the top channel structure and the bottom channel structure overlap with each other; where the top channel structure is located between the top source and the top drain, the bottom channel structure is located between the bottom source and the bottom drain, and the top channel structure and the bottom channel structure each includes a stack formed by a plurality of nanosheets; and
a gate, where the gate surrounds the plurality of nanosheets.

In an embodiment, the buried power line is provided parallel to channel directions of the top channel structure and the bottom channel structure.

In an embodiment, channel directions of the first CFET and the third CFET are aligned along a straight line, and channel directions of the second CFET and the fourth CFET are aligned along another straight line.

In an embodiment, the first CFET and the second CFET each further includes a top ground connection layer and a bottom ground connection layer,
where the top ground connection layer is in contact with the top source, the bottom ground connection layer is in contact with the bottom source, and the top ground connection layer is connected to the bottom ground connection layer.

A method for manufacturing an SRAM unit is provided according to the present disclosure. The method includes:
providing a substrate;
forming a first complementary field-effect transistor (CFET) and a third CFET on the substrate in a first direction, and forming a fourth CFET and a second CFET on the substrate in a second direction, where the first CFET, the second CFET, the third CFET and the fourth CFET each includes an upper transistor and a lower transistor, a conductivity type of the upper transistor is N-type, a conductivity type of the lower transistor is P-type, and the first direction and the second direction are parallel to each other; and
forming only one buried power line in the substrate between the first direction and the second direction.

In an embodiment, the forming a first CFET and a third CFET on the substrate in a first direction, and forming a fourth CFET and a second CFET on the substrate in a second direction, includes:
forming a plurality of stacked structures formed by alternately stacking first semiconductor layers and second semiconductor layers on a side of the substrate, where in a direction perpendicular to a plane where the substrate is located, the stacked structure includes a buffer layer located at a middle region;
etching the stacked structures in the first direction and the second direction, to form fin structures;
forming, after the buried power line is formed, the lower transistor based on the fin structures; and
forming the upper transistor based on the fin structures.

In an embodiment, the forming only one buried power line in the substrate between the first direction and the second direction, includes:
forming an insulation layer that overlays the fin structures, etching the insulation layer between two fin structures, to form a recess; and
forming the buried power line in the recess.

In an embodiment, before the forming the upper transistor based on the fin structures, the method further includes: forming a buried power connection layer connected to bottom sources of the lower transistors in the first CFET and the second CFET, where the buried power connection layer is electrically connected to the buried power line.

In an embodiment, before the forming the upper transistor based on the fin structures, the method further includes:
forming a first storage bottom electrode connected to a bottom drain of the lower transistor in the first CFET, and forming a second storage bottom electrode connected to a bottom drain of the lower transistor in the second CFET,
where after the forming the upper transistor based on the fin structures, the method further includes:
forming a first storage top electrode connected to a top drain of the upper transistor in the first CFET and a top source of the upper transistor in the third CFET, where the first storage bottom electrode and the first storage top electrode constitute a first storage electrode; and
forming a second storage top electrode connected to a top drain of the upper transistor in the second CFET and a top source of the upper transistor in the fourth CFET, where the second storage bottom electrode and the second storage top electrode constitute a second storage electrode.

In an embodiment, after the forming the upper transistor based on the fin structures, the method further includes:
forming a third dielectric layer on the substrate; and
etching the third dielectric layer to form a second groove, and forming a ground connection layer and a top ground connection layer connected to top sources of the upper transistors in the first CFET and the second CFET in the second groove, where the ground connection layer connects the top ground connection layer and a bottom ground connection layer.

A method for manufacturing a complementary field-effect transistor is provided according to the present disclosure. The method includes:
providing a substrate, and forming a plurality of stacked structures formed by alternately stacking first semiconductor layers and second semiconductor layers on a side of the substrate, where in a direction perpendicular to a plane where the substrate is located, the stacked structure includes a buffer layer located at a middle region;
etching the stacked structure and a partial thickness of the substrate to form a fin structure, where the fin structure includes a top structure, a bottom structure and a substrate structure, the top structure and the bottom structure is separated by the buffer layer, and a buried power line is formed between two substrate structures;
etching the top structure and the buffer layer, to form a top source region and a top drain region, where a top channel region is located between the top source region and the top drain region;
forming a third spacer on a sidewall of the top structure, and etching the bottom structure by using the third spacer as a mask, to form a bottom source region and a bottom drain region, where a bottom channel region is located between the bottom source region and the bottom drain region;
forming a bottom source in the bottom source region and forming a bottom drain in the bottom drain region;
forming a buried power connection layer, a bottom ground connection layer, a bottom word line connection layer, a bottom bit line connection layer, a first storage bottom electrode and a second storage bottom electrode on the bottom source and the bottom drain, where the buried power connection layer is electrically connected to the buried power line;
forming a top source and a top drain on the buried power connection layer, the bottom ground connection layer, the bottom word line connection layer, the bottom bit line connection layer, the first storage bottom electrode and the second storage bottom electrode;
removing the first semiconductor layers in the top channel region and the bottom channel region, where a plurality of to-be-filled gaps are formed between the second semiconductor layers;
filling the plurality of to-be-filled gaps with a gate, where the gate surrounds the second semiconductor layers, and a top channel structure and a bottom channel structure are respectively formed by a stack of a plurality of the second semiconductor layers; and
forming a top ground connection layer, a top word line connection layer, a top bit line connection layer, a first storage top electrode and a second storage top electrode respectively on the top source and the top drain, where the top ground connection layer is connected to the bottom ground connection layer.

In an embodiment, before the forming a buried power connection layer, a bottom ground connection layer, a bottom word line connection layer, a bottom bit line connection layer, a first storage bottom electrode and a second storage bottom electrode on the bottom source and the bottom drain, the method further includes:
forming a first dielectric layer, where the first dielectric layer overlays the top structure; and
etching the first dielectric layer on both sides of the top structure, to form a first groove, where the bottom source and the bottom drain are exposed by the first groove,
where the forming a buried power connection layer, a bottom ground connection layer, a bottom word line connection layer, a bottom bit line connection layer, a first storage bottom electrode and a second storage bottom electrode on the bottom source and the bottom drain, includes:
forming the buried power connection layer, the bottom ground connection layer, the bottom word line connection layer, the bottom bit line connection layer, the first storage bottom electrode and the second storage bottom electrode on the bottom source and the bottom drain exposed by the first groove,
where the method further includes:
forming a second dielectric layer in the first groove; and
etching the first dielectric layer and the second dielectric layer to a surface of the buffer layer at a side away from the substrate,
where the forming a top source and a top drain on the buried power connection layer, the bottom ground connection layer, the bottom word line connection layer, the bottom bit line connection layer, the first storage bottom electrode and the second storage bottom electrode, includes:
forming the top source and the top drain on the first dielectric layer and the second dielectric layer, where the first dielectric layer and the second dielectric layer overlay the buried power connection layer, the bottom ground connection layer, the bottom word line connection layer, the bottom bit line connection layer, the first storage bottom electrode and the second storage bottom electrode.

In an embodiment, the plurality of to-be-filled gaps include an isolation gap formed by removing the buffer layer,
where before the filling the plurality of to-be-filled gaps with a gate that surrounds the second semiconductor layers, the method further includes:
forming a second-type work function layer in all the to-be-filled gaps;
filling an isolation layer in the isolation gap and the to-be-filled gap at the bottom structure;
removing the second-type work function layer located in the to-be-filled gap at the top structure, and forming a first-type work function layer in the to-be-filled gap at the top structure; and
removing the isolation layer.

In an embodiment, before the forming a top ground connection layer, a top word line connection layer, a top bit line connection layer, a first storage top electrode and a second storage top electrode respectively on the top source and the top drain, the method further includes:
forming a third dielectric layer on the top source and the top drain; and
etching the third dielectric layer on both sides of the top structure, to form a second groove, where the top source and the top drain are exposed by the second groove,
where the forming a top ground connection layer, a top word line connection layer, a top bit line connection layer, a first storage top electrode and a second storage top electrode respectively on the top source and the top drain, includes:
forming the top ground connection layer, the top word line connection layer, the top bit line connection layer, the first storage top electrode and the second storage top electrode respectively on the top source and the top drain exposed by the second groove.

In an embodiment, before the etching the top structure and the buffer layer, the method further includes:
forming a dummy gate and a second spacer. The second spacer is located at both sides of the dummy gate,
where the etching the top structure and the buffer layer, to form a top source region and a top drain region, includes:
etching the top structure and the buffer layer by using the dummy gate and the second spacer as a mask, to form the top source region and the top drain region.

A complementary field-effect transistor is provided according to the present disclosure. The complementary field-effect transistor includes:
a substrate;
a top source, a top drain, a top channel structure, a bottom source, a bottom drain and a bottom channel structure disposed on a side of the substrate, where in a direction perpendicular to a plane where the substrate is located, the top source and the bottom source overlap with each other, the top drain and the bottom drain overlap with each other, and the top channel structure and the bottom channel structure overlap with each other, where the top channel structure is located between the top source and the top drain, the bottom channel structure is located between the bottom source and the bottom drain, and the top channel structure and the bottom channel structure each includes a stack formed by a plurality of nanosheets;
a gate, where the gate surrounds the plurality of nanosheets; and
a top ground connection layer in contact with the top source, and a bottom ground connection layer in contact with the bottom source, where the top ground connection layer is connected to the bottom ground connection layer,
where a distance between a surface of the bottom ground connection layer at a side closed to the substrate and a surface of the bottom source at a side away from the substrate is less than a target threshold.

In an embodiment, the surface of the bottom ground connection layer at the side closed to the substrate is flush with the surface of the bottom source at the side away from the substrate.

In an embodiment, the complementary field-effect transistor further includes a buried power line, where a depth of the buried power line ranges from 5 nm to 1000 nm.

In an embodiment, the top ground connection layer and the bottom ground connection layer are made of one or more of W, Al, Cu, Co, Ti, Ru, Sc, Pt, Ta and nitride.

A static random-access memory is provided according to the present disclosure. The static random-access memory includes a plurality of memory units, where the plurality of memory units each includes the complementary field-effect transistor according to any of the above embodiments.

An SRAM unit is provided according to the present disclosure. The SRAM unit includes: a substrate, and a first complementary field-effect transistor (CFET), a second CFET, a third CFET and a fourth CFET located on the substrate. The first CFET, the second CFET, the third CFET and the fourth CFET each includes an upper transistor and a lower transistor. A conductivity type of the upper transistor is N-type, and a conductivity type of the lower transistor is P-type. The upper transistors of the third CFET and the fourth CFET serve as gate transistors. In one SRAM unit, only one buried power line is included in the substrate.

### BRIEF DESCRIPTION OF THE DRAWINGS

To clearly illustrate technical solutions in embodiments of the present disclosure, drawings referred to describe the embodiments are briefly described hereinafter. Apparently, the drawings in the following description are only some embodiments of the present disclosure, and for those skilled in the art, other drawings may be acquired based on these drawings without any creative effort.

FIG. 1 is a schematic circuit diagram of a memory unit in a static random-access memory;

FIG. 2 is a schematic structural diagram of a memory unit in a static random-access memory;

FIG. 3 is a schematic structural diagram of another memory unit in a static random-access memory;

FIG. 4 is a schematic flowchart of a method for manufacturing a complementary field-effect transistor according to an embodiment of the present disclosure;

FIG. 5 is a schematic structural diagram of a memory unit in a static random-access memory according to an embodiment of the present disclosure;

FIG. 6 is a schematic diagram of a top tier of the schematic structural diagram provided in FIG. 5;

FIG. 7 is a schematic diagram of a bottom tier of the schematic structural diagram provided in FIG. 5;

FIG. 8 is a schematic three-dimensional structural diagram of a complementary field-effect transistor according to an embodiment of the present disclosure;

FIG. 9 to FIG. 67 are schematic structural diagrams of a complementary field-effect transistor manufactured using a method for manufacturing a complementary field effect transistor according to an embodiment of the present disclosure;

FIG. 68 is a schematic structural diagram of another memory unit in a static random-access memory according to an embodiment of the present disclosure; and

FIG. 69 is a schematic flowchart of a method for manufacturing an SRAM unit according to an embodiment of the present disclosure.

### DETAILED DESCRIPTION

To enable those skilled in the art to better understand the solutions according to the present disclosure, technical solutions of embodiments of the present disclosure are clearly and completely described hereinafter in conjunction with the drawings of the embodiments of the present disclosure. Apparently, the embodiments described are only some embodiments of the present disclosure, rather than all embodiments. Based on the embodiments of the present disclosure, all other embodiments obtained by those skilled in the art without any creative effort fall within the protection scope of the present disclosure.

Various specific details are set forth in following description to facilitate a full understanding of the present disclosure. The present disclosure may be implemented in a manner different from those described herein, and those skilled in the art may perform analogous promotion without departing from concepts of the present disclosure. Therefore, the present disclosure is not limited by the embodiments disclosed hereinafter.

The present disclosure is described in detail in conjunction with schematic diagrams. To facilitate description in describing embodiments of the present disclosure in detail, a cross-sectional structural diagram of a device is partially enlarged, not on a general scale. The schematic diagrams are merely exemplary, which are not intended to limit the protection scope of present disclosure. In addition, three-dimensional spatial dimensions of length, width, and depth shall be configured in practice.

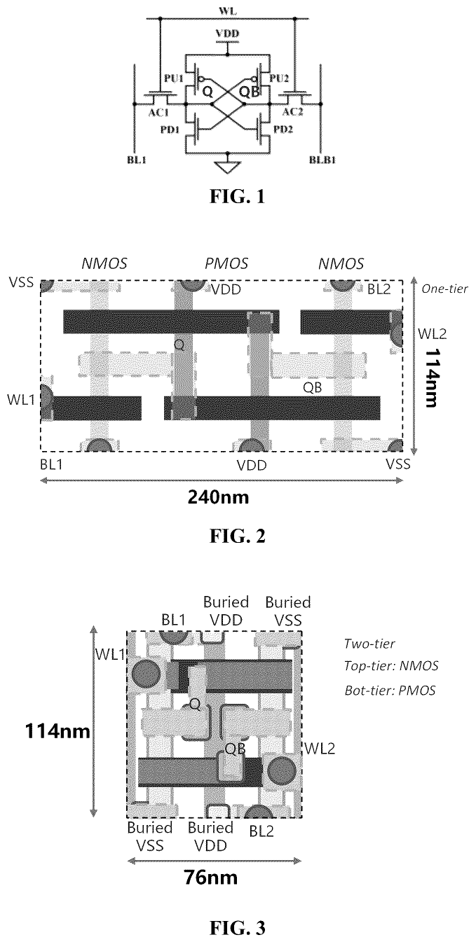

Reference is made to FIG. 1, which is a schematic circuit diagram of a memory unit in a static random-access memory. A memory unit of a static random-access memory (SRAM) is referred to as a bit, which can only store a single signal, either 0 or 1. Such a bit consists of 6 transistors, including two P metal-oxide-semiconductor field-effect transistors (PMOS) and four N metal-oxide-semiconductor field-effect transistors (NMOS). In FIG. 1, PU1 and PU2 are PMOS, and PD1, PD2, AC1 and AC2 are NMOS. Q and QB represent storage bits. In FIG. 1, VDD represents a power supply terminal, VSS represents a ground terminal, WL represents a word line, and BL represents a bit line.

Reference is made to FIGS. 2 and 3, which are schematic structural diagrams of two memory unit in a static random-access memory. FIG. 2 shows planar transistors, which only have a one-tier structure. FIG. 3 shows complementary field-effect transistors, which have a two-tier structure, where a top-tier structure is NMOS, and a bottom-tier (bot-tier) structure is PMOS. By configuring the memory unit with complementary field-effect transistors instead of planar transistors, the length of the memory unit is shortened from 240 nm to 76 nm, and the area of the memory unit in the static random-access memory is greatly reduced.

However, a requirement for a smaller area of the memory unit in the static random-access memory still exists.

Based on this, an SRAM unit is provided according to the present disclosure. The SRAM unit includes: a substrate, and a first complementary field-effect transistor (CFET), a second CFET, a third CFET and a fourth CFET located on the substrate. The first CFET, the second CFET, the third CFET and the fourth CFET each includes an upper transistor and a lower transistor. A conductivity type of the upper transistor is N-type, and a conductivity type of the lower transistor is P-type. The upper transistors of the third CFET and the fourth CFET serve as gate transistors. In one SRAM unit, only one buried power line is included in the substrate. That is, only the buried power line is formed in the substrate, while no buried ground line is provided, reducing the wiring space for grounding, and further reducing the area of a memory unit in the static random-access memory.

To facilitate understanding technical solutions and technical effects of the present disclosure, hereinafter embodiments are described in detail in conjunction with the drawings.

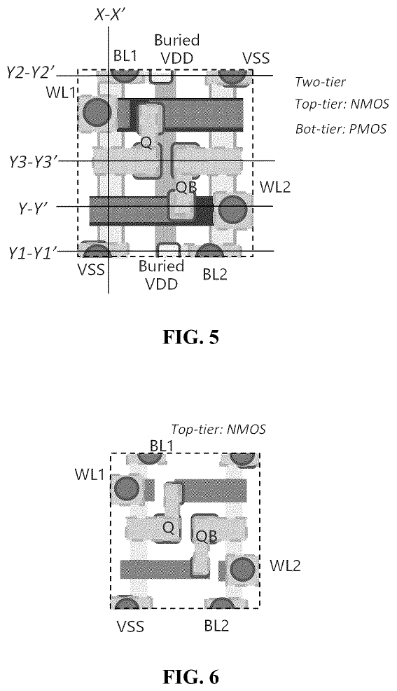

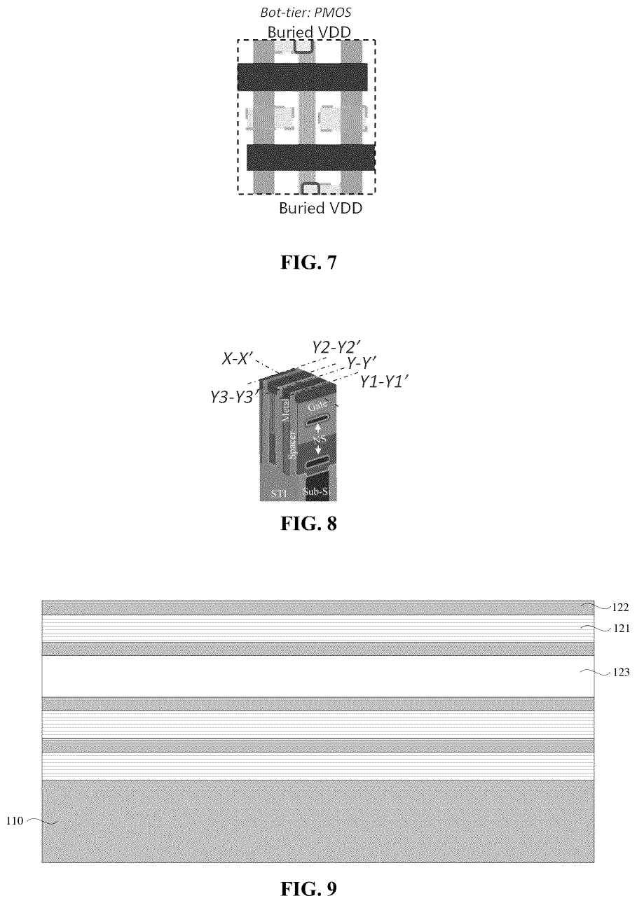

Reference is made to FIG. 5, which is a schematic structural diagram of a memory unit in a static random-access memory according to an embodiment of the present disclosure. The structure of the memory unit in FIG. 5 includes two tiers, where a top tier is NMOS (referred to FIG. 6), and a bottom tier is PMOS (referred to FIG. 7).

An SRAM unit according to an embodiment of the present disclosure includes a substrate 110 and four complementary field-effect transistors (CFET) on the substrate 110, which are a first CFET, a second CFET, a third CFET and a fourth CFET respectively. The first CFET, the second CFET, the third CFET and the fourth CFET each includes an upper transistor and a lower transistor. A conductivity type of the upper transistor is N-type, and a conductivity type of the lower transistor is P-type. That is, each CFET includes two transistors stacked vertically. The upper transistor is an NMOS transistor, and the lower transistor is a PMOS transistor. The upper transistor of the third CFET and the upper transistor of the fourth CFET serve as gate transistors.

In one SRAM unit, only one buried power line (buried VDD) 310 is included in the substrate 110. As can be seen from FIG. 7, the buried power line 310 may be provided to achieve power connection of the complementary field effect transistors.

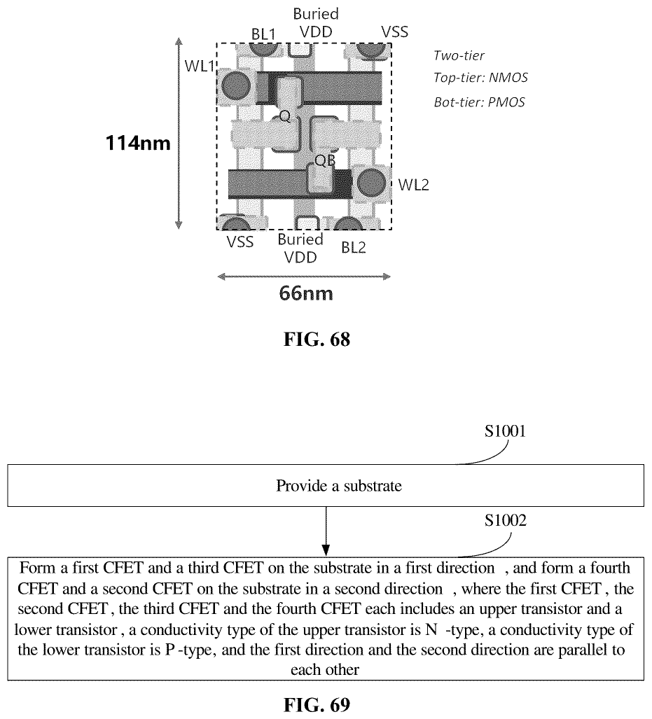

That is, in one SRAM unit, no buried ground line is formed in the substrate 110, reducing the wiring space that would otherwise be occupied by the buried ground line. The power connection can be achieved by providing only one buried power line 310, greatly reducing the area of the SRAM unit. Compared with a traditional technology of providing a buried ground line, the absence of the buried ground line can reduce the wiring space for grounding, and the length of a memory unit in the static random-access memory can be shortened from 76 nm to 66 nm, as illustrated in FIG. 68, thereby reducing the area of the memory unit. In addition, an etching process for high aspect ratio is not required, reducing a process requirement for high aspect ratio etching and filling metal materials. Moreover, since no buried ground line is provided, a distance between a power supply plane and a ground line plane is large, thus avoiding crosstalk and improving the performance of the manufactured SRAM unit. A specific value of area reduction of the memory unit shown in FIG. 68 is merely an example, and the actual extent of the area reduction in the present disclosure is not limited.

In an embodiment, the buried power line 310 is connected to a power supply, to supply power to the SRAM unit through the buried power line 310 by using the power supply.

In an embodiment, a depth of the buried power line 310 ranges from 5 nm to 1000 nm.

In an embodiment of the present disclosure, the first CFET, the second CFET, the third CFET and the fourth CFET each includes: a top source 133, a top drain 134, a top channel structure, a bottom source 131, a bottom drain 132 and a bottom channel structure disposed on a side of the substrate. In a direction perpendicular to a plane where the substrate 110 is located, the top source 133 and the bottom source 131 overlap with each other, the top drain 134 and the bottom drain 132 overlap with each other, and the top channel structure and the bottom channel structure overlap with each other. The top channel structure is located between the top source 133 and the top drain 134, and the bottom channel structure is located between the bottom source 131 and the bottom drain 132. The top channel structure and the bottom channel structure each includes a stack formed by a plurality of nanosheets.

The first CFET, the second CFET, the third CFET and the fourth CFET each includes: a gate 160. The gate 160 surrounds the plurality of nanosheets.

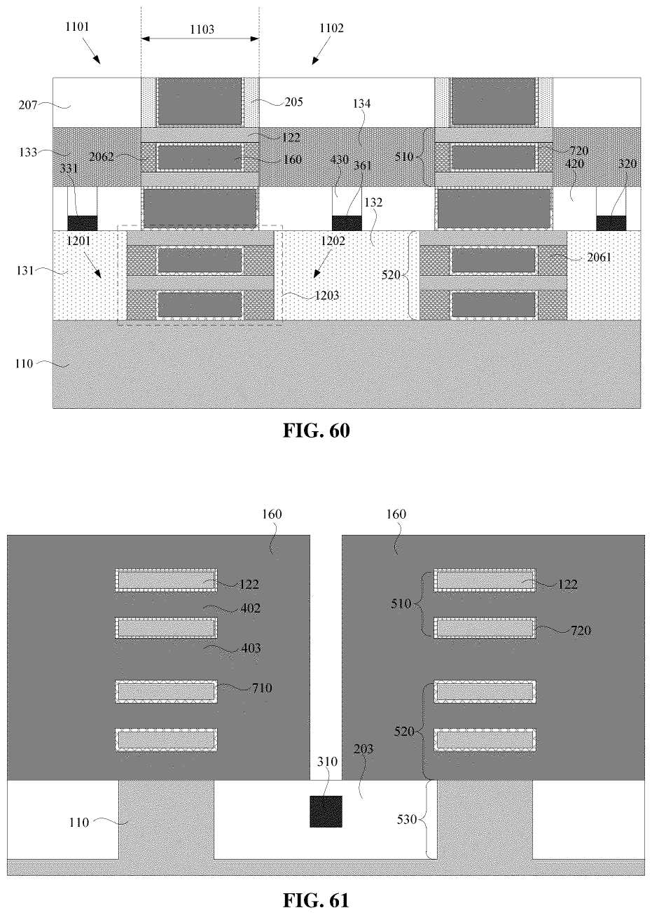

Reference is made to FIGS. 60 and 61, which show structures of the first CFET and the fourth CFET. The upper transistor and the lower transistor of the first CFET may be surrounded by one gate 160, and the upper transistor and the lower transistor of the fourth CFET may be surrounded by another gate 160.

In an embodiment of the present disclosure, the bottom sources 131 of the lower transistors in the first CFET and the second CFET are connected to a buried power connection layer 320. The buried power connection layer 320 is electrically connected to the buried power line 310, thereby achieving power connection through the bottom sources 131 of the lower transistors in the first CFET and the second CFET.

In an embodiment of the present disclosure, the buried power line 310 is provided parallel to channel directions of the top channel structure and the bottom channel structure. As shown in FIG. 5 or FIG. 7, the buried power line 310 is aligned along an X-X′ direction, and the channel directions of the top channel structure and the bottom channel structure are also aligned along the X-X′ direction.

In an embodiment of the present disclosure, channel directions of the first CFET and the third CFET are aligned along a straight line, and channel directions of the second CFET and the fourth CFET are aligned along another straight line. The two straight lines are parallel to each other. That is, the first CFET and the third CFET are disposed along one straight line, and the second CFET and the fourth CFET are disposed along another parallel straight line.

As an example, the first CFET and the third CFET are aligned along a left straight line in the X-X′ direction in FIG. 5, and the second CFET and the fourth CFET are aligned along a right straight line in the X-X′ direction in FIG. 5. The third CFET is connected to a first word line (WL1) and a first bit line (BL1), and the first CFET lies on the same straight line with the third CFET. The fourth CFET is connected to a second word line (WL2) and a second bit line (BL2), and the second CFET lies on the same straight line as the fourth CFET. That is, in FIG. 5, the third CFET is located at an upper left corner, the first CFET is located at a lower left corner, the second CFET is located at an upper right corner, and the fourth CFET is located at a lower right corner.

In an embodiment of the present disclosure, the bottom drain 132 of the lower transistor of the first CFET is connected to a first storage bottom electrode 361. The top drain 134 of the upper transistor of the first CFET and the top source 133 of the upper transistor of the third CFET are connected to a first storage top electrode 362. The first storage bottom electrode 361 and the first storage top electrode 362 constitute a first storage electrode. The first storage electrode may be a Q storage electrode.

The bottom drain 132 of the lower transistor in the second CFET is connected to a second storage bottom electrode 371. The top source 133 of the upper transistor in the second CFET and the top drain 134 of the upper transistor in the fourth CFET are connected to a second storage top electrode 372. The second storage bottom electrode 371 and the second storage top electrode 372 constitute a second storage electrode, and the second storage electrode may be a QB storage electrode.

In an embodiment of the present disclosure, the first CFET and the second CFET each further includes a top ground connection layer 332 and a bottom ground connection layer 331. The top ground connection layer 332 is in contact with the top source 133, and the bottom ground connection layer 331 is in contact with the bottom source 131. The top ground connection layer 332 and the bottom ground connection layer 331 are connected with each other. That is, the top sources 133 of the upper transistors in the first CFET and the second CFET are grounded. That is, the complementary field-effect transistor may be grounded by using the top ground connection layer 332 and the bottom ground connection layer 331 without providing a buried ground line, reducing the wiring space for grounding, and further reducing the area of the memory unit in the static random-access memory.

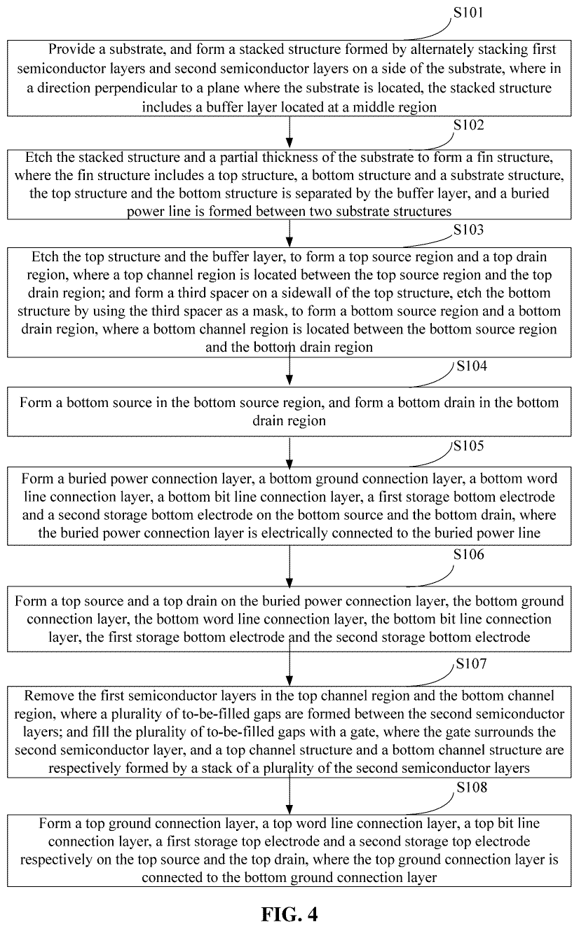

Reference is made to FIG. 4, which is a schematic flowchart of a method for manufacturing a complementary field-effect transistor according to an embodiment of the present disclosure.

In the embodiment of the present disclosure, the complementary field-effect transistor is manufactured according to the schematic structural diagram of a memory unit in a static random-access memory shown in FIG. 5.

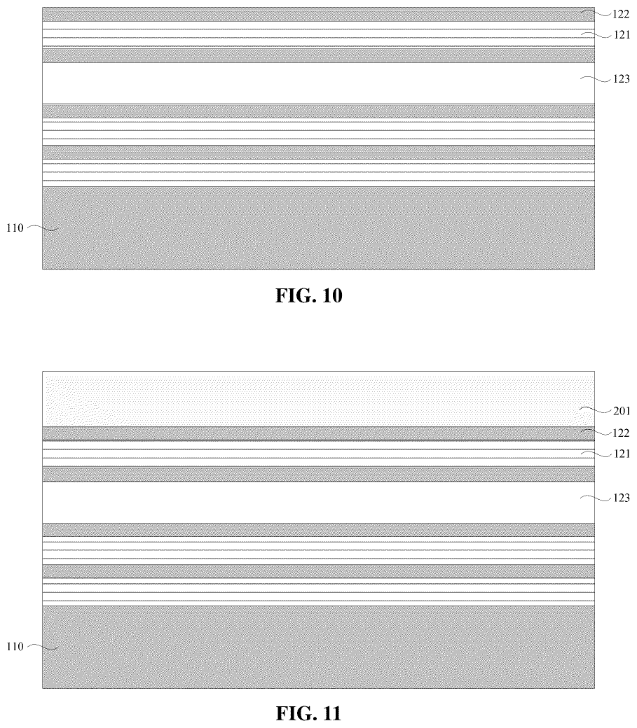

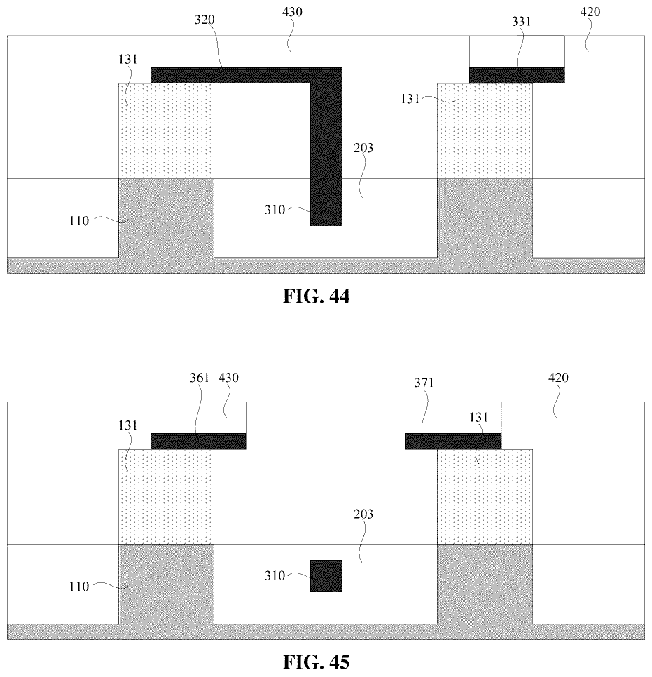

FIG. 8 is a schematic three-dimensional structural diagram of a complementary field-effect transistor according to an embodiment of the present disclosure. A plurality of cross-sectional structural diagrams of the complementary field-effect transistor are obtained by taking cross-sections along directions of X-X′, Y-Y′, Y1-Y1′, Y2-Y2′, and Y3-Y3′ on the schematic perspective structural diagram, respectively. FIGS. 9, 11, 13, 15, 17, 19, 21, 23, 25, 27, 28, 29, 30, 31, 32, 34, 36, 40, 42, 46, 47, 48, 50, 52, 54, 56, 58, 60, 62 and 64 are schematic cross-sectional structural diagrams along the X-X′ direction. FIGS. 10, 12, 14, 16, 18, 20, 22, 24, 26, 33, 49, 51, 53, 55, 57, 59 and 61 are schematic cross-sectional structural diagrams along the Y-Y′ direction. FIGS. 37, 41, 43 and 65 are schematic cross-sectional structural diagrams along the Y1-Y1′ direction. FIGS. 35, 38, 44 and 66 are schematic cross-sectional structural diagrams along the Y2-Y2′ direction. FIGS. 39, 45, 63 and 67 are schematic cross-sectional structural diagrams along the Y3-Y3′ direction.

The method for manufacturing a complementary field-effect transistor according to an embodiment of the present disclosure includes the following steps.

In step S101, a substrate is provided, a stacked structure formed by alternately stacking first semiconductor layers and second semiconductor layers is formed on a side of the substrate, where in a direction perpendicular to a plane where the substrate is located, the stacked structure includes a buffer layer located at a middle region, as shown in FIGS. 9 and 10.

In an embodiment of the present disclosure, a substrate 110 may be a semiconductor substrate, such as a bulk silicon substrate, and the substrate 110 may be doped to obtain a P-type semiconductor substrate or an N-type semiconductor substrate, such as a P-type silicon substrate or an N-type silicon substrate.

As an example, impurities are implanted into a bulk silicon substrate, and a highly-doped well region may be formed after annealing, to achieve a desired well depth. For different device types, the doping type of the substrate 110 varies. For a p-type semiconductor device, the highly-doped well region is N-well, and the implanted impurities are n-type impurity ions, such as phosphorus (P) ions. For an N-type semiconductor device, the highly-doped well region is p-well, and the implanted impurities are p-type impurity ions, such as boron (B) ions.

In an embodiment of the present disclosure, a stacked structure formed by alternately stacking first semiconductor layers 121 and second semiconductor layers 122 may be formed on a side of the substrate 110, as shown in FIGS. 9 and 10.

In an embodiment, for different device types, a material of the first semiconductor layers 121 and a material of the second semiconductor layers 122 may be the same. For example, the first semiconductor layers 121 may be made of silicon germanium, and the second semiconductor layers 122 may be made of silicon or germanium. For different device types, the material of the first semiconductor layers 121 and the material of the second semiconductor layers 122 may be different. For example, for a P-type semiconductor device, the first semiconductor layers 121 may be made of silicon, and the second semiconductor layers 122 may be made of silicon germanium. For an N-type semiconductor device, the first semiconductor layers 121 may be made of silicon germanium, and the second semiconductor layers 122 may be made of silicon.

Considering that two transistors of different doping types stacked vertically may be formed by using the stacked structure, when the material is silicon, silicon with different doping types may also be adopted. For example, the second semiconductor layer 122 located at the top is made of P-type doped silicon, and the second semiconductor layer 122 located at the bottom may be made of N-type doped silicon.

In the direction perpendicular to the plane where the substrate 110 is located, the stacked structure includes a buffer layer 123 located at a middle region. The buffer layer 123 is configured for separating two transistors of different doping types stacked vertically. The buffer layer 123 may be made of the same material as the first semiconductor layer 121, and a thickness of the buffer layer 123 may be larger than that of the first semiconductor layer 121. The second semiconductor layers 122 are provided on both sides of the buffer layer 123.

In practice, silicon oxide may be formed on the substrate 110, and the stacked structure may be formed after removing the silicon oxide on the substrate 110 and cleaning the substrate 110.

In step S102, the stacked structure and a partial thickness of the substrate are etched to form a fin structure. The fin structure includes a top structure, a bottom structure and a substrate structure, the top structure and the bottom structure is separated by the buffer layer, and a buried power line is formed between two substrate structures, as shown in FIG. 11 to FIG. 24.

In an embodiment of the present disclosure, the stacked structure and the partial thickness of the substrate 100 may be etched to form two fin structures. The fin structures each includes a top structure 510, a bottom structure 520 and a substrate structure 530. The top structure 510 and the bottom structure 520 are separated by the buffer layer 123. After the fin structures are formed, a buried power supply line 310 may be formed between the substrate structures 530 included in the two fin structures, without forming a buried ground line. The process flow of forming the fin structures and the buried power line 310 is described in detail below.

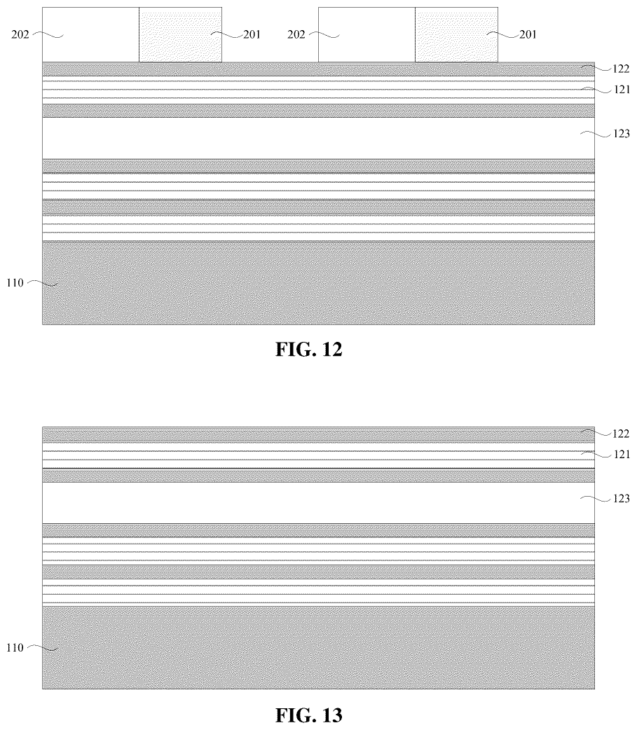

In step S1021, a spacer transfer process is performed, as shown in FIGS. 11 and 12.

In an embodiment of the present disclosure, a self-aligned spacer transfer process is used to form a first spacer 201. The first spacer 201 is made of silicon nitride, and a specific formation procedure is as follows. A sacrificial layer 202 is covered on the stacked structure, where the sacrificial layer 202 may be made of polycrystalline silicon or amorphous silicon. Part of the sacrificial layer 202 is removed by performing patterned etching through photolithography, silicon nitride material is deposited, anisotropic etching is then used to remove the remaining sacrificial layer 202, and only the first spacer 201 is retained on the stacked structure. The first spacer 201 acts as a hard mask in the subsequent photolithography for forming a fin.

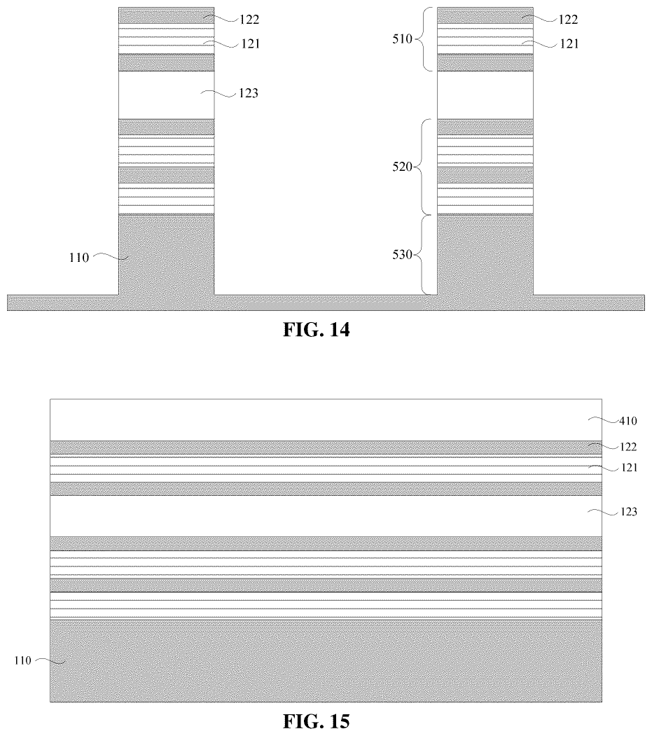

In step S1022, the fin structure is formed, as shown in FIGS. 13 and 14.

In an embodiment of the present disclosure, the stacked structure and the partial thickness of the substrate may be etched through an etching process, to form a plurality of periodically distributed fins, as shown in FIGS. 13 and 14. Etching is performed by using the first spacer 201 as a mask, to form a fin with a stacked structure. An upper portion of the fin includes the top structure 510 and the bottom structure 520 formed by the stacked structure, the top structure 510 and the bottom structure 520 are separated by the buffer layer 123, the top structure 510 and the bottom structure 520 serve as channel regions, a lower portion of the fin includes the substrate 110, and the fin as shown in FIG. 14 is formed. The fin includes not only a stacked structure, but also a monocrystalline silicon structure that extends to the substrate 110. The etching process may be dry etching or wet etching. In an embodiment, reactive ion etching may be adopted. The fin structure would be used to form a nanosheet of a complementary field-effect transistor. Although FIG. 14 shows two fins, it should be understood that any suitable number and form of fins can be used in practice.

In practice, the first spacer 201 may be removed after the fin structure is formed.

In step S1023, the buried power line 310 is formed, as shown in FIGS. 15 to 22.

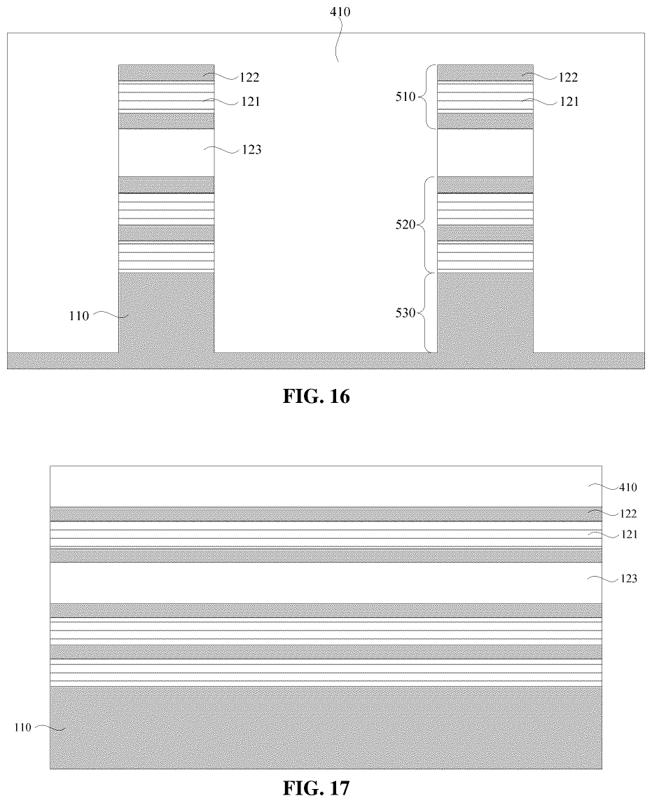

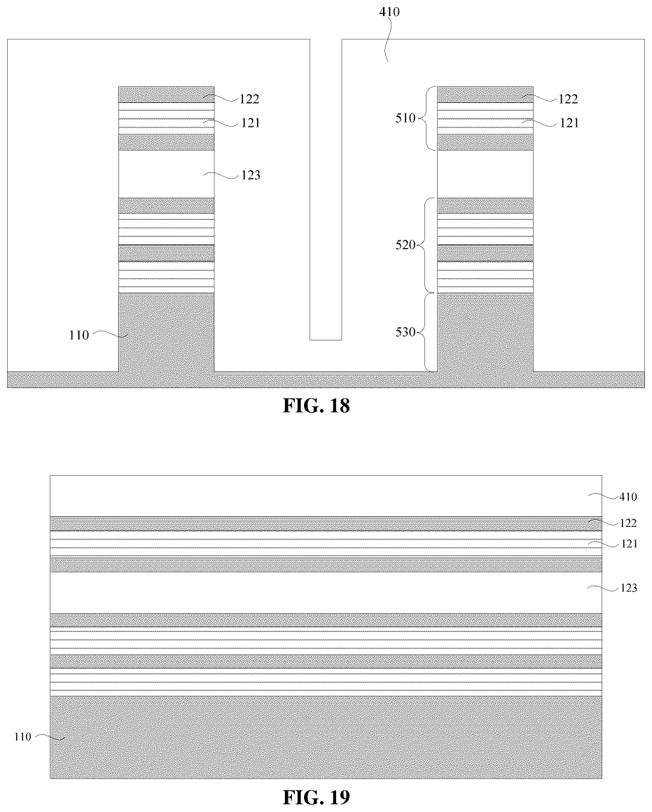

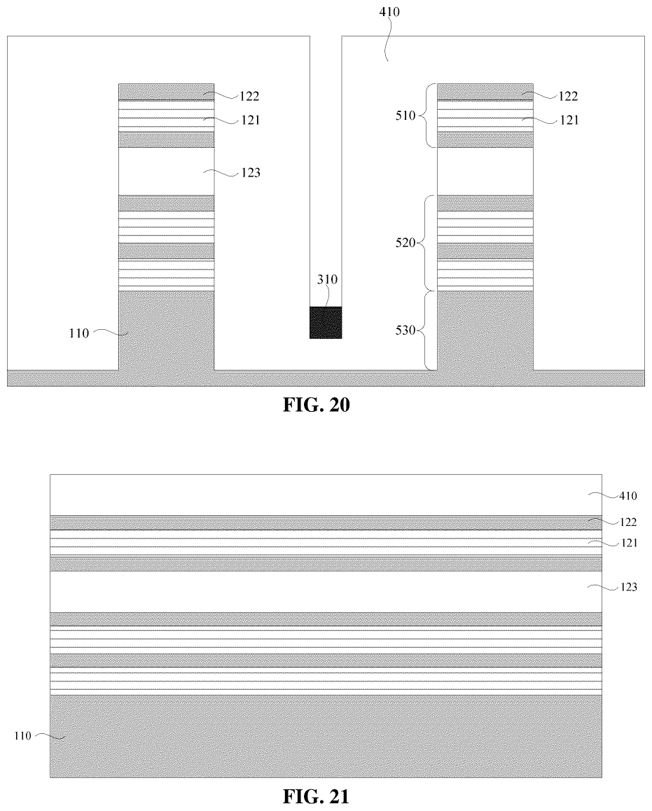

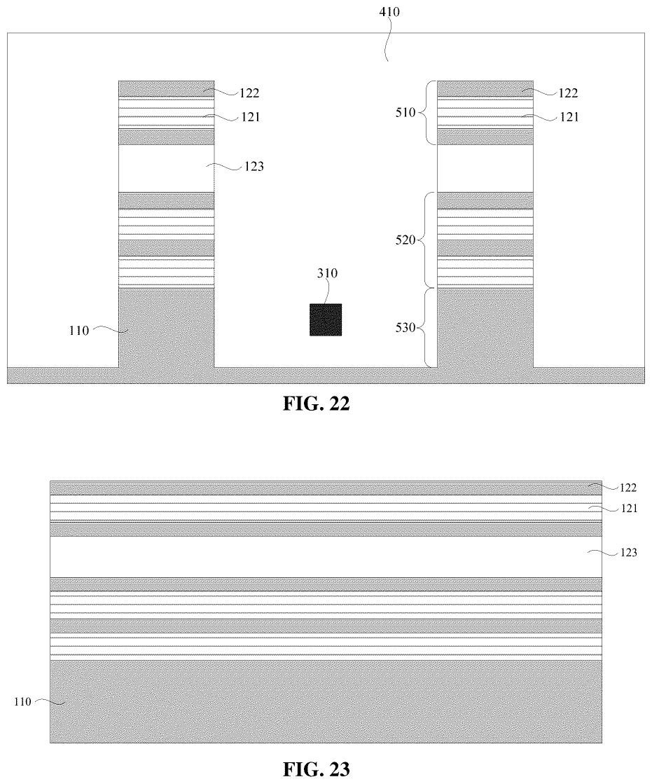

In an embodiment of the present disclosure, the buried power line 310 may be formed between the substrate structures 530 of the two fin structures. In an embodiment, dielectric insulating material is deposited, and then planarization, such as a chemical mechanical planarization (CMP) process, is performed, to form the insulation layer 410, referring to FIGS. 15 and 16. The insulation layer 410 between the two fin structures is etched to a depth of an area where the substrate structure 530 is located, to form a recess, referring to FIGS. 17 and 18. The recess formed by etching is filled with metal material, such as tungsten (W), and then planarization and etchback are performed, to form the buried power line 310, referring to FIGS. 19 and 20. Finally, the dielectric insulating material is continued to be deposited, and then planarization is performed, to fill the recess, referring to FIGS. 21 and 22.

In practice, the buried power line 310 may be replaced by a ground line (VSS) or another power voltage plane (VCC).

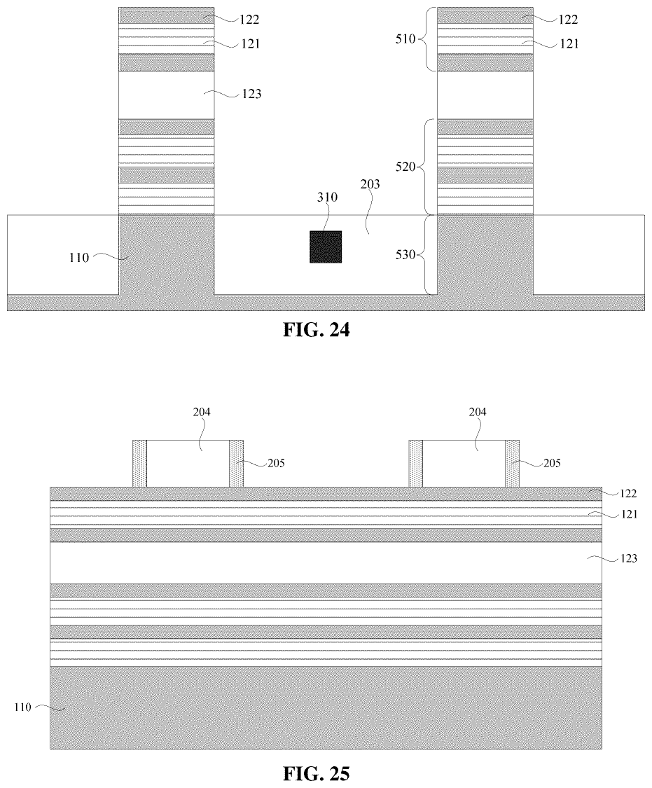

In step S1024, shallow trench isolation (STI) 203 is formed, as shown in FIGS. 23 and 24.

In an embodiment of the present disclosure, the shallow trench isolation 203 may be formed between different fins. In an embodiment, a selective etchback process is performed on the insulation layer 410 formed in step S1023, to expose the three-dimensional fins. The top structure 510 and the bottom structure 520 are exposed, to form the shallow trench isolation 203 near the fin structures. A surface of the shallow trench isolation 203 at a side away from the substrate 110 may be flush with, or may be higher or lower than, a surface of the stacked structure in the fin structure at a side near the substrate 110. The shallow trench isolation 203 may be made of suitable dielectric material, such as silicon dioxide or silicon nitride. The function of the shallow trench isolation 203 is to separate channels on adjacent fin structures.

In step S103, the top structure and the buffer layer are etched, to form a top source region and a top drain region, where a top channel region is located between the top source region and the top drain region. A third spacer is formed on a sidewall of the top structure, the bottom structure is etched by using the third spacer as a mask, to form a bottom source region and a bottom drain region, where a bottom channel region is located between the bottom source region and the bottom drain region, as shown in FIGS. 25 to 29.

In an embodiment of the present disclosure, considering that two transistors of different doping types stacked vertically need to be formed in the subsequent, it is to form sources and drains of the two transistors separately. First, a source region and a drain region of the two transistors are to be formed, and the specific process is described in detail below.

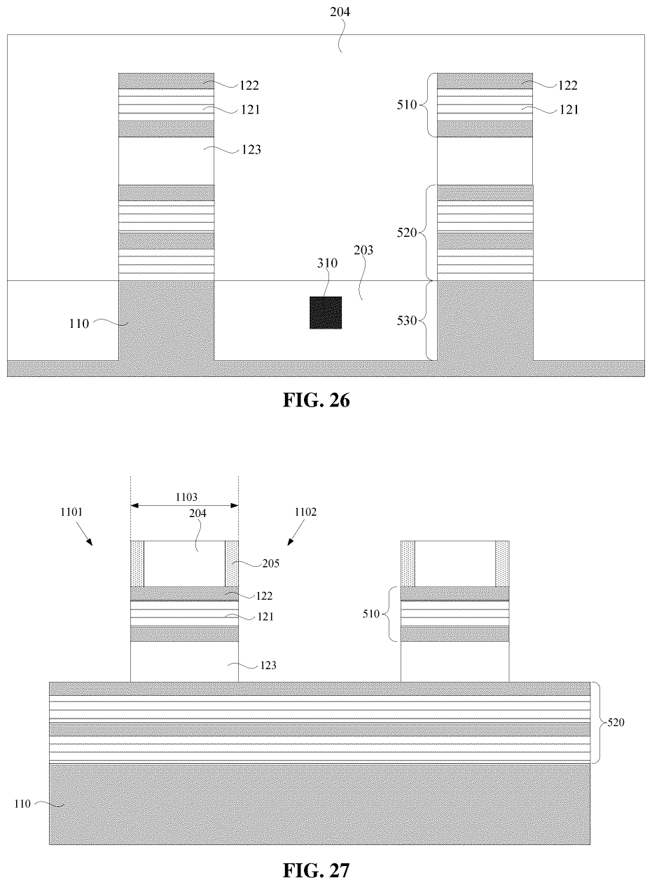

In step S1031, a dummy gate 204 and a second spacer 205 are formed, as shown in FIGS. 25 and 26.

In an embodiment of the present disclosure, in a direction perpendicular to a fin line, i.e., an X-X′ direction, a dummy gate stack is formed on the exposed fin structure. The dummy gate stack has a multi-layer structure, which includes a gate insulating dielectric layer (not shown), the dummy gate 204 and a hard mask layer (not shown). The dummy gate stack may be formed by processes such as thermal oxidation, chemical vapor deposition, or sputtering. The dummy gate stack spans a stacked structure at an upper part of the fin structure, and a plurality of dummy gates are periodically distributed along a direction of a fin line. The dummy gate 204 may be made of polycrystalline silicon or amorphous silicon. The hard mask layer may be made of oxide, carbide, organic matter, etc.

In an embodiment of the present disclosure, second spacers 205 having the same thickness may be provided on both sides of the dummy gate stack along the direction of the fin line, i.e., the Y-Y′ direction, respectively. The second spacer 205 may be made of dielectric material having isolation properties, such as silicon nitride or doped silicon oxide.

In step S1032, the top structure 510 and the buffer layer 123 are etched, to form a top source region 1101 and a top drain region 1102, as shown in FIG. 27.

In an embodiment of the present disclosure, after the dummy gate 204 and the second spacer 205 are formed, the dummy gate 204 and the second spacer 205 may be used as a mask, and source-drain etching is performed on the stacked structure. In an embodiment, the source-drain etching is performed on the top structure 510 and the buffer layer 123, to form the top source region 1101 and the top drain region 1102. A top channel region 1103 is located between the top source region 1101 and the top drain region 1102. The top source region 1101 and the top drain region 1102 no longer have a stacked structure after being formed by etching, as shown in FIG. 27.

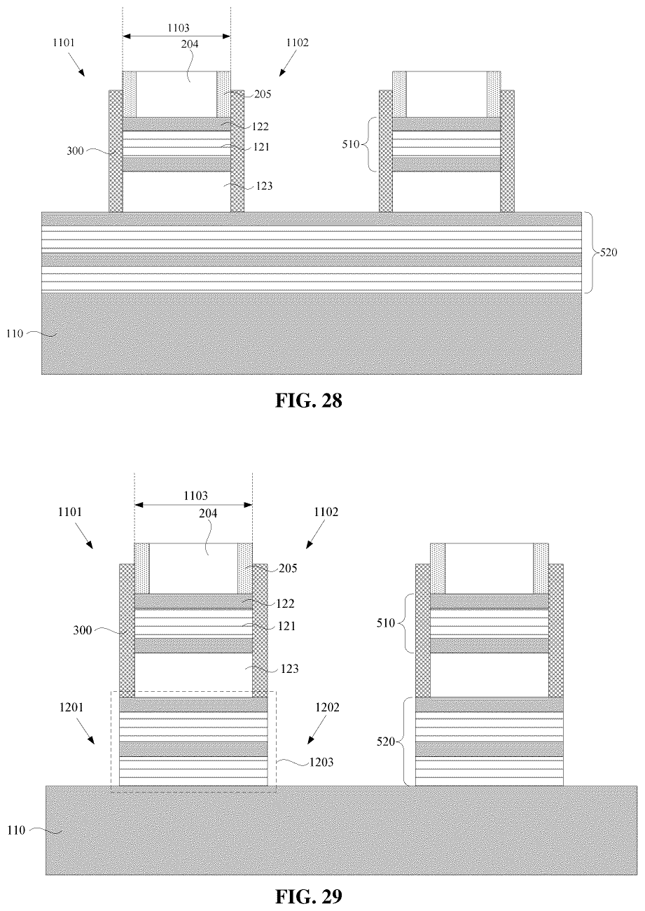

In step S1033, a third spacer 300 is formed on a sidewall of the top structure 510, as shown in FIG. 28.

In an embodiment of the present disclosure, after the top structure 510 and the buffer layer 123 are etched to obtain the top source region 1101 and the top drain region 1102, the third spacer 300 may be formed on the sidewall of the top structure 510. That is, third spacers 300 may be provided on both sides of the etched stacked structure along the direction of the fin line, i.e., the Y-Y′ direction, respectively. The third spacers 300 on both sides have the same thickness. The third spacer 300 may be made of dielectric material having isolation properties, such as silicon nitride or doped silicon oxide. Referring to FIG. 28, the third spacer 300 also overlays a sidewall the second spacer 205.

In step S1034, the bottom structure 520 is etched by using the third spacer 300 as a mask, to form a bottom source region 1201 and a bottom drain region 1202, as shown in FIG. 29.

In an embodiment of the present disclosure, after the third spacer 300 is formed, source-drain etching is performed on the stacked structure by using the dummy gate 204, the second spacer 205 and the third spacer 300 as a mask. In an embodiment, source-drain etching is performed on the bottom structure 520, to form the bottom source region 1201 and the bottom drain region 1202. A bottom channel region 1203 is located between the bottom source region 1201 and the bottom drain region 1202. The bottom source region 1201 and the bottom drain region 1202 no longer have a stacked structure after being formed by etching, as shown in FIG. 29.

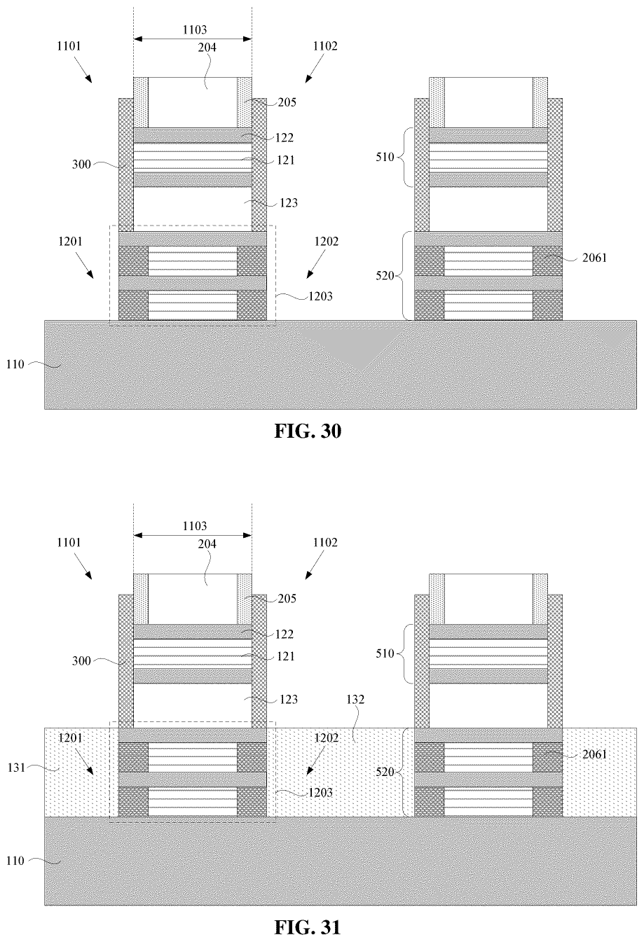

In step S104, a bottom source is formed in the bottom source region, and a bottom drain is formed in the bottom drain region, as shown in FIGS. 30 and 31.

In an embodiment of the present disclosure, after the stacked structure is etched to form the bottom source region 1201 and the bottom drain region 1202, a bottom source 131 and a bottom drain 132 may be respectively formed on the bottom source region 1201 and the bottom drain region 1202, as shown in FIG. 31. Surfaces of the bottom source 131 and the bottom drain 132 at sides away from the substrate 110 may be flush with a surface of the buffer layer 123 at a side closed to the substrate 110.

In an embodiment, for different types of semiconductor devices, a material of a source and a material of a drain may be different. For a P-type semiconductor device, the source and the drain are made of boron-doped silicon germanium, i.e., SiGe:B; and for an N-type semiconductor device, the source and the drain are made of carbon-doped silicon, i.e., Si:C.

In an embodiment of the present disclosure, before forming the bottom source 131 and the bottom drain 132, a bottom inner spacer may be formed on a sidewall of the fin along the Y-Y′ direction, and the specific process is as follows.

In step S1041, a concave structure is formed.

In an embodiment of the present disclosure, the first semiconductor layer 121 in the bottom structure 520 is selectively etched in the Y-Y′ direction. That is, only the first semiconductor layer 121 is etched without damaging the second semiconductor layer 122. A missing part of the first semiconductor layer 121 compared to the second semiconductor layer 122 forms a concave structure in the Y-Y′ direction. That is, pull-back etching is performed to etch a part of the first semiconductor layer 121 in a direction from the bottom source region 1201 and the bottom drain region 1202 to the bottom channel region 1203.

In step S1042, a bottom inner spacer 2061 is formed, as shown in FIG. 30.

In an embodiment of the present disclosure, after etching on the first semiconductor layer 121 is finished, dielectric material is deposited on the bottom structure 520 in the bottom channel region 1203, that is, on an outer periphery of the fin, and the dielectric material is etched to form the bottom inner spacer 2061. The bottom inner spacer 2061 is flush with the second semiconductor layer 122 in a direction perpendicular to the plane where the substrate 110 is located. That is, the concave structure formed by etching in S1041 is filled by the bottom inner spacer 2061. The material of the bottom inner spacer 2061 may be silicon nitride or silicon oxide.

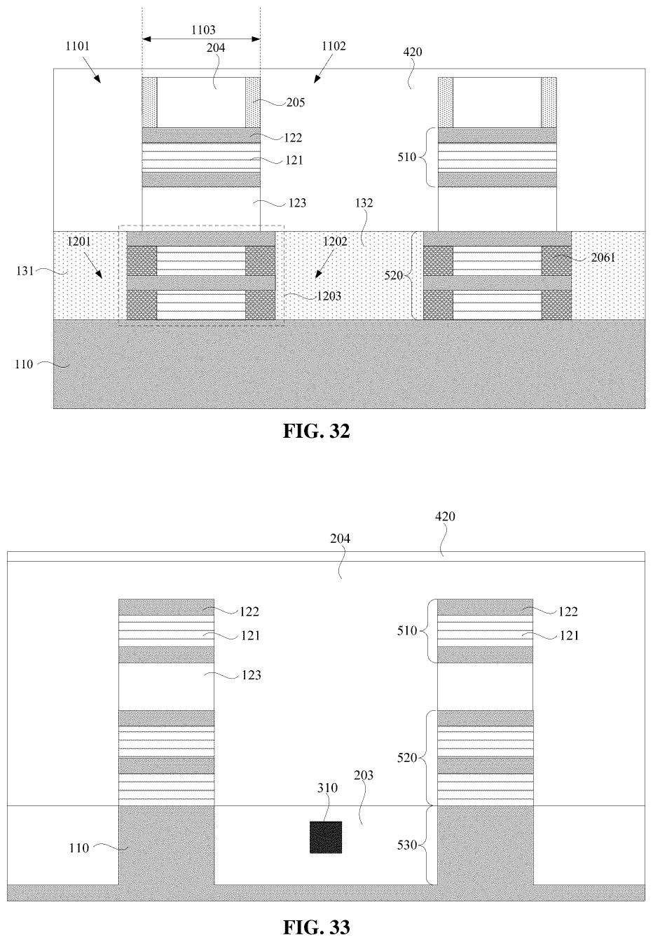

In step S105, a buried power connection layer, a bottom ground connection layer, a bottom word line connection layer, a bottom bit line connection layer, a first storage bottom electrode and a second storage bottom electrode are formed on the bottom source and the bottom drain, where the buried power connection layer is electrically connected to the buried power line, as shown in FIGS. 32 to 45.

In an embodiment of the present disclosure, considering that electrical connection is required when forming two transistors stacked vertically in the subsequent, after the bottom source 131 and the bottom drain 132 are formed, a buried power connection layer 320, a bottom ground connection layer 331, a bottom word line connection layer, a bottom bit line connection layer, a first storage bottom electrode 361 and a second storage bottom electrode 371 may be formed on the bottom source 131 and the bottom drain 132, and the buried power connection layer 320 is electrically connected to the buried power line 310. The specific formation process is described in detail below.

In step S1051, a first dielectric layer 420 is formed, where the first dielectric layer 420 overlays the top structure 510, as shown in FIGS. 32 and 33.

In an embodiment of the present disclosure, after the bottom source 131 and the bottom drain 132 are formed, the third spacer 300 may be removed. Dielectric material is then deposited, and planarization is performed, to form the first dielectric layer 420, where the first dielectric layer 420 overlays the top structure 510, referring to FIGS. 32 and 33.

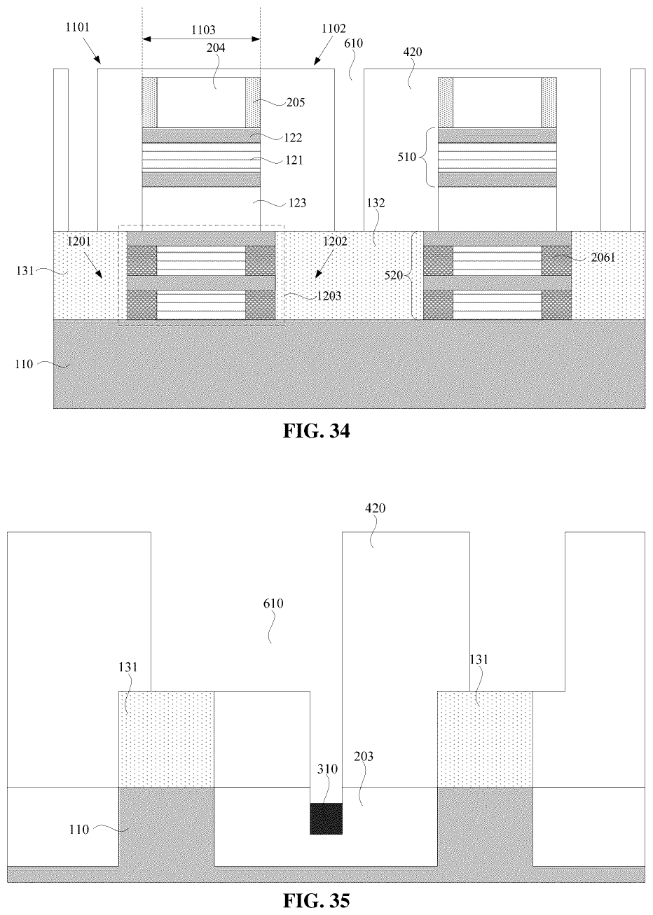

In step S1052, the first dielectric layer 420 on both sides of the top structure 510 is etched, to form a first groove 610, where the bottom source 131 and the bottom drain 132 are exposed by the first groove 610, referring to FIGS. 34 and 35.

In an embodiment of the present disclosure, after the first dielectric layer 420 is formed, the first dielectric layer 420 on both sides of the top structure 510 may be etched to the bottom source 131 and the bottom drain 132, to form the first groove 610, and the bottom source 131 and the bottom drain 132 are exposed by the first groove 610, as shown in FIG. 34. The buried power line 310 is also exposed by the first groove 610, as shown in FIG. 35.

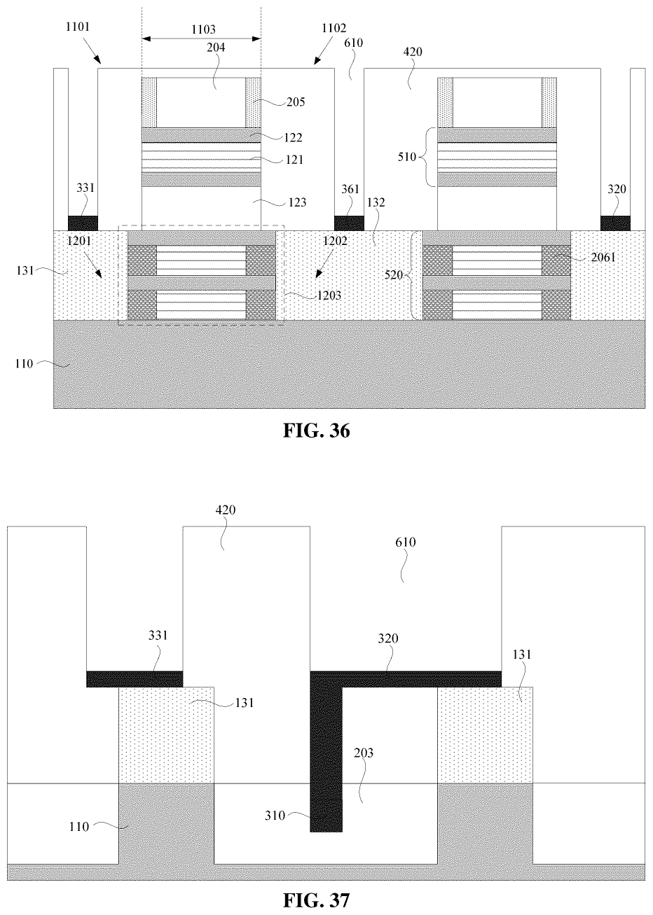

In step S1053, the buried power connection layer 320, the bottom ground connection layer 331, the bottom word line connection layer, the bottom bit line connection layer, the first storage bottom electrode 361 and the second storage bottom electrode 371 are formed on the bottom source 131 and the bottom drain 132 exposed by the first groove 610, referring to FIGS. 36, 37, 38 and 39.

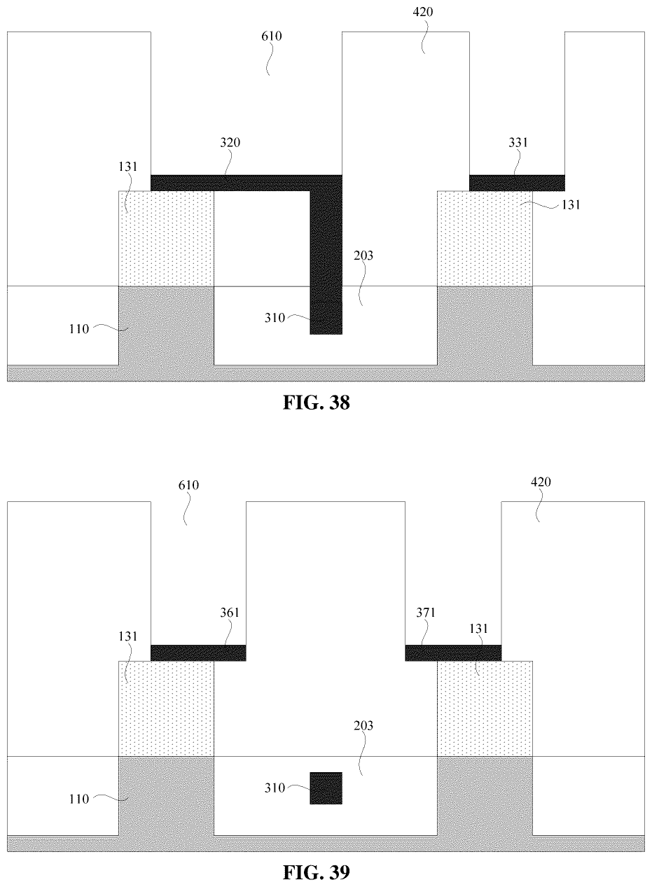

In an embodiment of the present disclosure, after the first groove 610 exposing the bottom source 131 and the bottom drain 132 is formed, the bottom ground connection layer 331, the first storage bottom electrode 361 and the bottom bit line connection layer may be formed on the bottom source 131 and the bottom drain 132 exposed by the first groove 610, as shown in FIG. 36. The first storage bottom electrode 361 and the second storage bottom electrode 371 are formed on the bottom source 131 and the bottom drain 132 exposed by the first groove 610, referring to FIG. 39. The buried power connection layer 320 and the bottom ground connection layer 331 are formed on the bottom source 131 and the bottom drain 132 exposed by the first groove 610, and the buried power connection layer 320 is electrically connected to the buried power line 310, referring to FIGS. 37 and 38. In addition, the bottom word line connection layer is formed on the bottom source 131 and the bottom drain 132 exposed by the first groove 610.

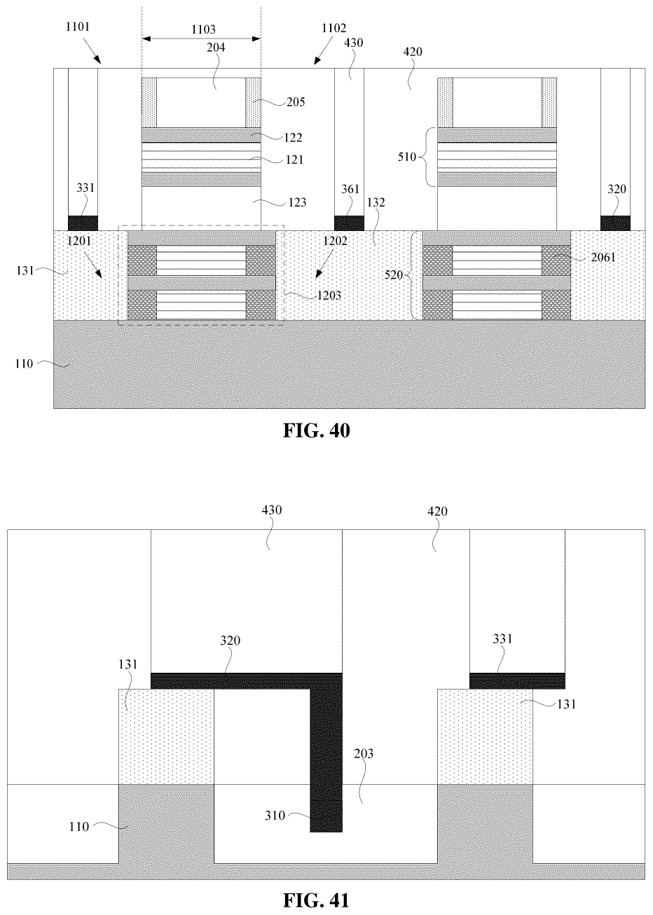

In step S1054, a second dielectric layer 430 is formed in the first groove 610, as shown in FIGS. 40 and 41.

In an embodiment of the present disclosure, after the buried power connection layer 320, the bottom ground connection layer 331, the bottom word line connection layer, the bottom bit line connection layer, the first storage bottom electrode 361 and the second storage bottom electrode 371 are formed, dielectric material may be deposited in the first groove 610, and then planarization is performed, to form the second dielectric layer 430, as shown in FIGS. 40 and 41. Materials of the first dielectric layer 420 and the second dielectric layer 430 may be the same.

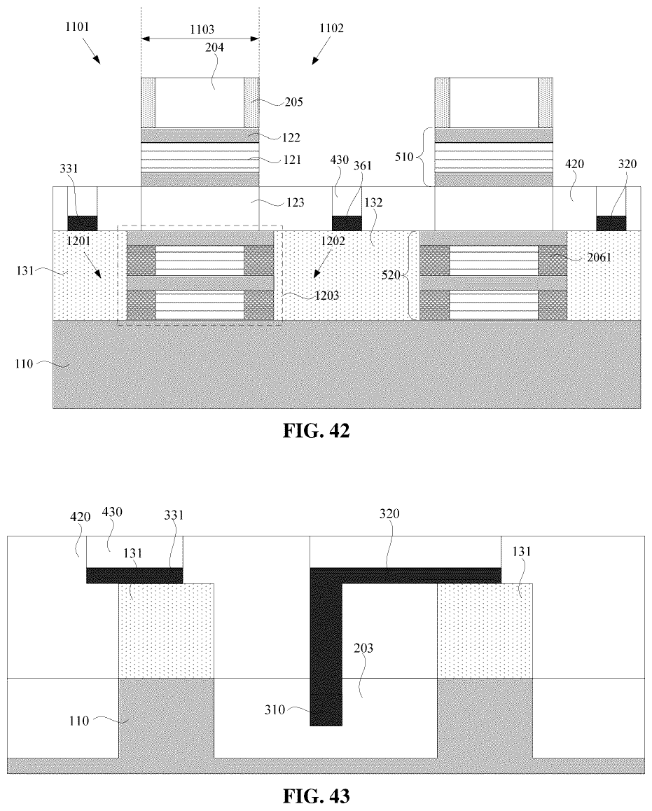

In step S1055, the first dielectric layer 420 and the second dielectric layer 430 are etched such that a side surface of the first dielectric layer 420 and the second dielectric layer 430 that is away from the substrate 110 is flush with a side surface of the buffer layer 123 that is away from the substrate 110, as shown in FIGS. 42, 43, 44, and 45.

In an embodiment of the present disclosure, after the second dielectric layer 430 is formed, the first dielectric layer 420 and the second dielectric layer 430 may be etched back to a surface of the buffer layer 123 at a side away from the substrate 110, and the etched first dielectric layer 420 and the etched second dielectric layer 430 overlay the buried power connection layer 320, the bottom ground connection layer 331, the bottom word line connection layer, the bottom bit line connection layer, the first storage bottom electrode 361 and the second storage bottom electrode 371, as shown in FIGS. 42, 43, 44 and 45.

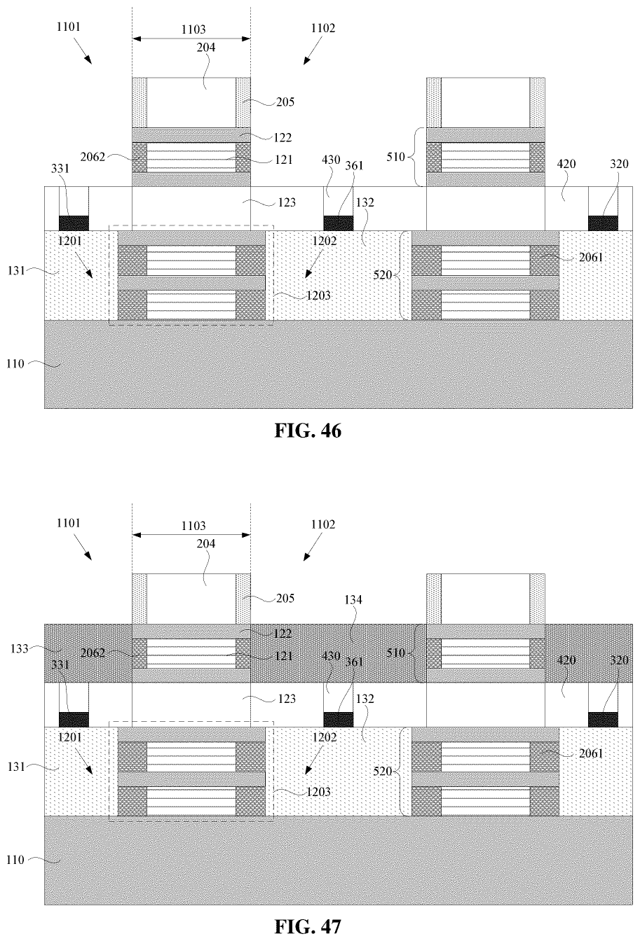

In step S106, a top source and a top drain are formed on the buried power connection layer, the bottom ground connection layer, the bottom word line connection layer, the bottom bit line connection layer, the first storage bottom electrode and the second storage bottom electrode, referring to FIGS. 46 and 47.

In an embodiment of the present disclosure, after the buried power connection layer 320, the bottom ground connection layer 331, the bottom word line connection layer, the bottom bit line connection layer, the first storage bottom electrode 361 and the second storage bottom electrode 371 are formed, the top source 133 and the top drain 134 may be formed on the buried power connection layer 320, the bottom ground connection layer 331, the bottom word line connection layer, the bottom bit line connection layer, the first storage bottom electrode 361 and the second storage bottom electrode 371, to form the source and the drain of the upper transistor of the two transistors stacked vertically, as shown in FIG. 47. The top source 133 and the top drain 134 may be specifically located at the first dielectric layer 420 and the second dielectric layer 430.

In an embodiment, for different types of semiconductor devices, a material of a source and a material of a drain may be different. For a P-type semiconductor device, the source and the drain are made of boron-doped silicon germanium, i.e., SiGe:B; and for an N-type semiconductor device, the source and the drain are made of carbon-doped silicon, i.e., Si:C.

In an embodiment of the present disclosure, before forming the top source 133 and the top drain 134, a top inner spacer may also be formed on a sidewall of the fin in the Y-Y′ direction, and the specific process flow is as follows.

In step S1061, a concave structure is formed.

In an embodiment of the present disclosure, the first semiconductor layer 121 in the top structure 510 is selectively etched in the Y-Y′ direction. That is, only the first semiconductor layer 121 is etched without damaging the second semiconductor layer 122. A missing part of the first semiconductor layer 121 compared to the second semiconductor layer 122 forms a concave structure in the Y-Y′ direction. That is, pull-back etching is performed to etch a part of the first semiconductor layer 121 in a direction from the top source region 1101 and the top drain region 1102 to the top channel region 1103.

In step S1062, a top inner spacer 2062 is formed, as shown in FIG. 46.

In an embodiment of the present disclosure, after etching on the first semiconductor layer 121 is finished, dielectric material is deposited on the top structure 510 in the top channel region 1103, that is, on an outer periphery of the fin, and the dielectric material is etched to form a top inner spacer 2062. The top inner spacer 2062 is flush with the second semiconductor layer 122 in a direction perpendicular to the plane where the substrate 110 is located. That is, the concave structure formed by etching in S1061 is filled by the top inner spacer 2062. The material of the top inner spacer 2062 may be silicon nitride or silicon oxide.

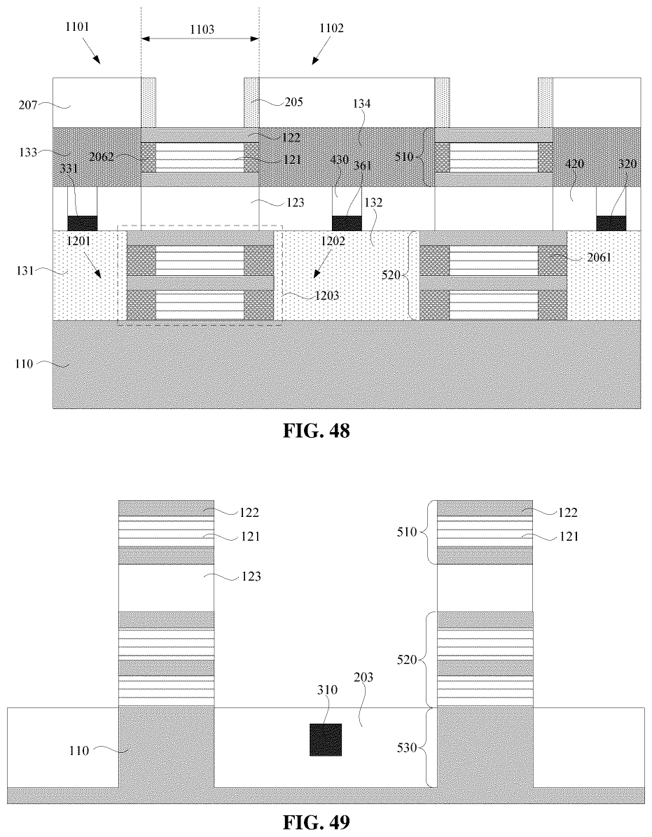

In step S107, the first semiconductor layers in the top channel region and the bottom channel region is removed, where a plurality of to-be-filled gaps are formed between the second semiconductor layers. The plurality of to-be-filled gaps are filled with a gate, where the gate surrounds the second semiconductor layer, and a top channel structure and a bottom channel structure are respectively formed by a stack of a plurality of the second semiconductor layers, referring to FIG. 48 to FIG. 61.

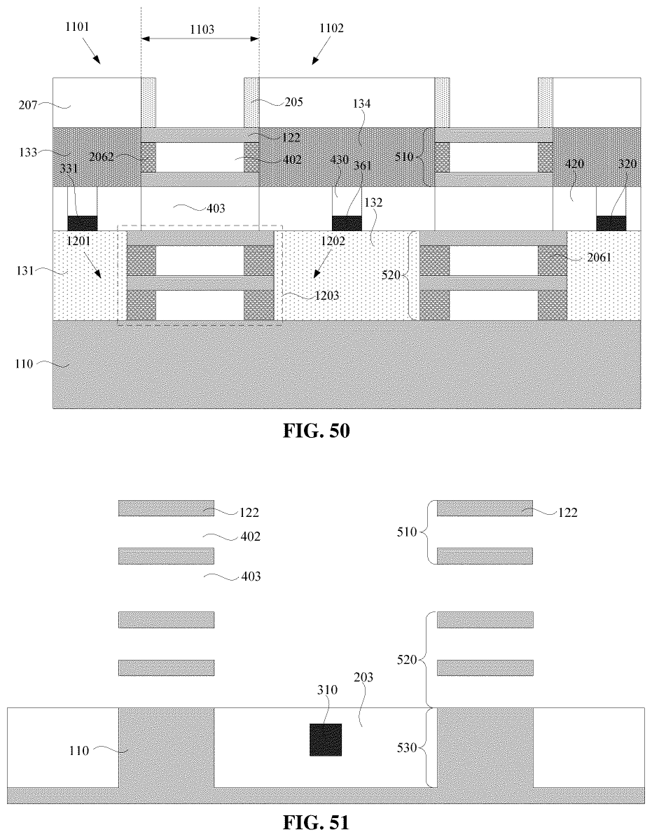

In an embodiment of the present disclosure, the first semiconductor layers 121 in the top channel region 1103 and the bottom channel region 1203 may be removed, that is, a nanosheet channel release procedure is performed, to form a plurality of to-be-filled gaps 402 between the second semiconductor layers 122, as shown in FIGS. 50 and 51. The plurality of to-be-filled gaps 402 is then filled with a gate 160, as shown in FIGS. 60 and 61.

In an embodiment, the first semiconductor layers 121 in the stacked structure located in the top channel region 1103 and the bottom channel region 1203 may be selectively etched to perform nanosheet channel release. That is, the stacked structure exposed on the fins is processed. The first semiconductor layer 121 for each layer is removed, that is, the first semiconductor layer 121 serves as a sacrificial layer, and a nanosheet formed by the second semiconductor layer 122 is released.

The buffer layer 123 is also removed while removing the first semiconductor layer 121. That is, the formed plurality of to-be-filled gaps 402 include an isolation gap 403 formed by removing the buffer layer 123, as shown in FIGS. 50 and 51.

In an embodiment of the present disclosure, for different types of devices, several possible implementations for nanosheet channel release are as follows.

In a first possible implementation, for P-type and N-type semiconductor devices, the first semiconductor layer 121, which serves as a sacrificial layer, is made of silicon germanium. By selectively removing the silicon germanium, the second semiconductor layer 122, which is made of silicon, is retained to form a silicon-stacked nanosheet stack device. In a selective removal process, an etchant that may selectively etch silicon germanium at a faster rate relative to silicon may be adopted.

In a second possible implementation, for a P-type semiconductor device, the first semiconductor layer 121, which serves as the sacrificial layer, is made of silicon. By selectively removing the silicon, the second semiconductor layer 122, which is made of silicon germanium, is retained to form a silicon-germanium-stacked nanosheet stack device. In the selective removal process, an etchant that can selectively etch silicon at a faster rate relative to silicon germanium may be used.

In a third possible implementation, for an N-type semiconductor device, the first semiconductor layer 121, which serves as a sacrificial layer, is made of silicon germanium. By selectively removing the silicon germanium, the second semiconductor layer 122, which is made of silicon, is retained to form a silicon-stacked nanosheet stack device. In the selective removal process, an etchant that can selectively etch silicon germanium at a faster rate relative to silicon may be used.

In an embodiment of the present disclosure, a dummy gate 204 may be removed before the first semiconductor layers 121 in the top channel region 1103 and the bottom channel region 1203 are removed, and the specific process flow is as follows.

In step S1071, the dummy gate 204 is removed, as shown in FIGS. 48 and 49.

In an embodiment of the present disclosure, a spacer layer 207 may be deposited on surfaces of the dummy gate 204, the top source 133 and the top drain 134, to prevent a short circuit caused by interconnection between the dummy gate 204 and the top source 133 or the top drain 1342 in a subsequent step, and a chemical mechanical polishing process is performed on the isolation layers 207 for planarization. Then, as shown in FIGS. 48 and 49, the dummy gate 204 formed of the polycrystalline silicon or amorphous silicon is etched or corroded by a selective etching or corrosion process, that is, the dummy gate 204 is removed.

In an embodiment of the present disclosure, after the plurality of to-be-filled gaps 402 are formed, an interface layer may be formed on a surface of the second semiconductor layer 122, and an interface between the interface layer and the second semiconductor layer 122 may be passivated. In an embodiment, the interface layer may be made of silicon oxide.

In an embodiment of the present disclosure, after forming the interface layer, a high-κ dielectric layer may be formed at a surface of the interface layer, and the high-κ dielectric layer surrounds the surface of the interface layer. In an embodiment, a material of the high-κ dielectric layer may be one or a combination of any of HfO₂, HfSiOₓ, HfON, HfSiON, HfAlOₓ, HfLaOₓ, Al₂O₃, ZrO₂, ZrSiOₓ, Ta₂O₅ or La₂O₃.

Considering that forming upper and lower transistors of different types needs to use an isolation layer to isolate different types of transistors and use different types of work function layers to realize different types of transistors, a specific process flow is described in the following.

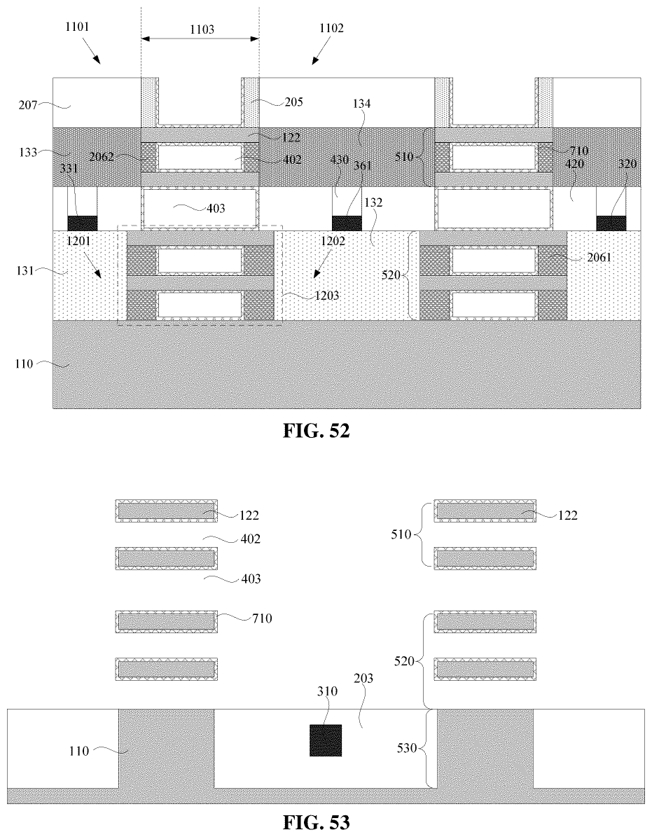

In step S1072, a second-type work function layer 710 is formed in all the to-be-filled gaps 402, as shown in FIGS. 52 and 53.

In an embodiment of the present disclosure, the second-type work function layer 710 may be formed in all the to-be-filled gaps 402, and the second-type work function layer 710 surrounds a surface of the high-k dielectric layer. In an embodiment, the second-type work function layer 710 is a P-type work function layer (P-WFL).

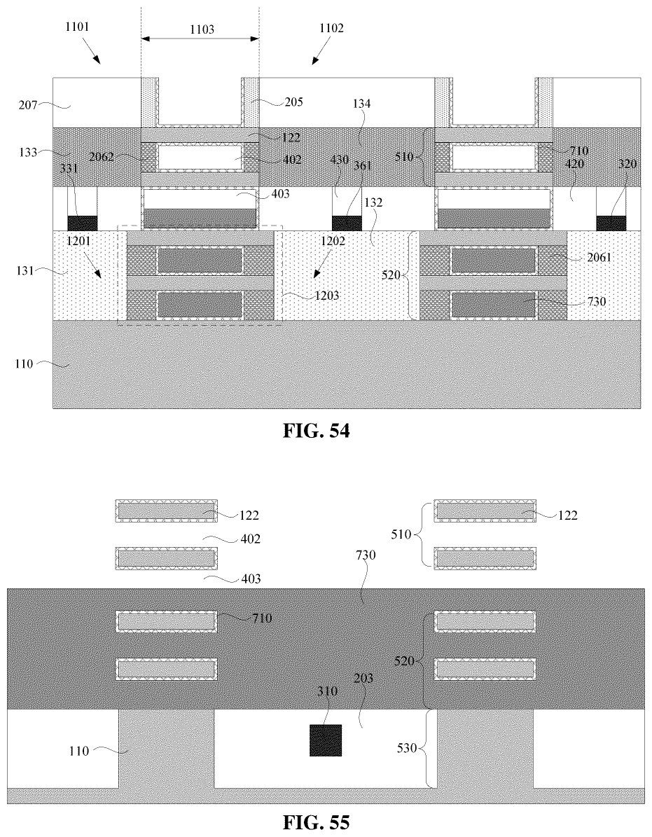

In step S1073, the isolation gap 403 and the to-be-filled gap 402 in the bottom structure 520 is filled with a protective layer 730, as shown in FIGS. 54 and 55.

In an embodiment of the present disclosure, isolation material may be deposited, and then the isolation material may be etched back to a position of the isolation gap 403, to form the protective layer 730. In an embodiment, the isolation material may be etched back to a ½ position of the isolation gap 403. Referring to FIGS. 54 and 55, a partial thickness of the isolation gap 403 and the to-be-filled gap 402 in the bottom structure 520 are filled with the protective layer 730.

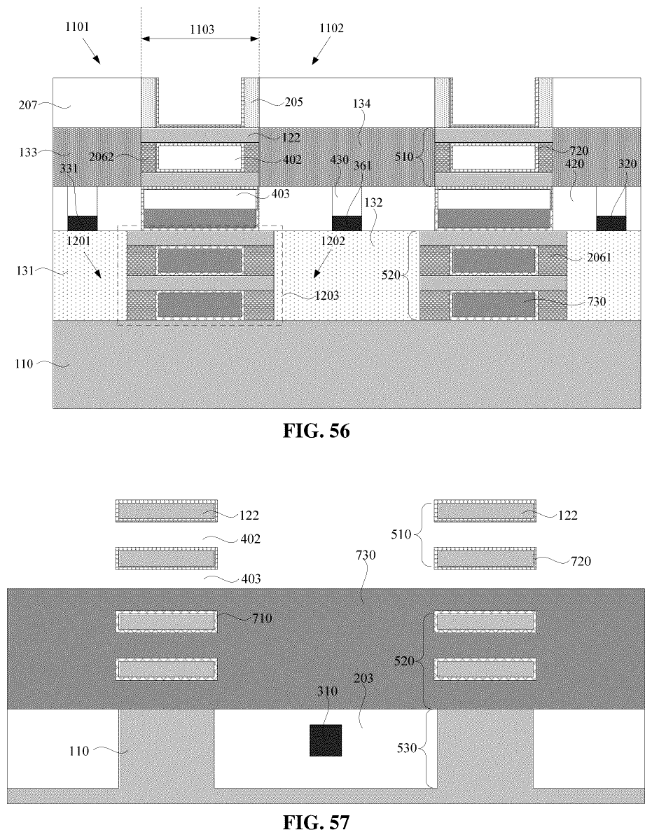

In step S1074, the second-type work function layer 710 located in the to-be-filled gap 402 in the top structure 510 is removed, and a first-type work function layer 720 is formed in the to-be-filled gap 402 in the top structure 510, referring to FIGS. 56 and 57.

In an embodiment of the present disclosure, the second-type work function layer 710 located in the to-be-filled gap 402 in the top structure 510 is removed by using the protective layer 730 as a mask, and the first-type work function layer 720 is formed in the to-be-filled gap 402 in the top structure 510, so that the first-type work function layer 720 is formed in the top structure 510, and the second-type work function layer 710 is formed in the bottom structure 520. In an embodiment, the first-type work function layer 720 is an N-type work function layer (N-WFL). The second-type work function layer 710 located in the to-be-filled gap 402 in the top structure 510 may be removed by etching.

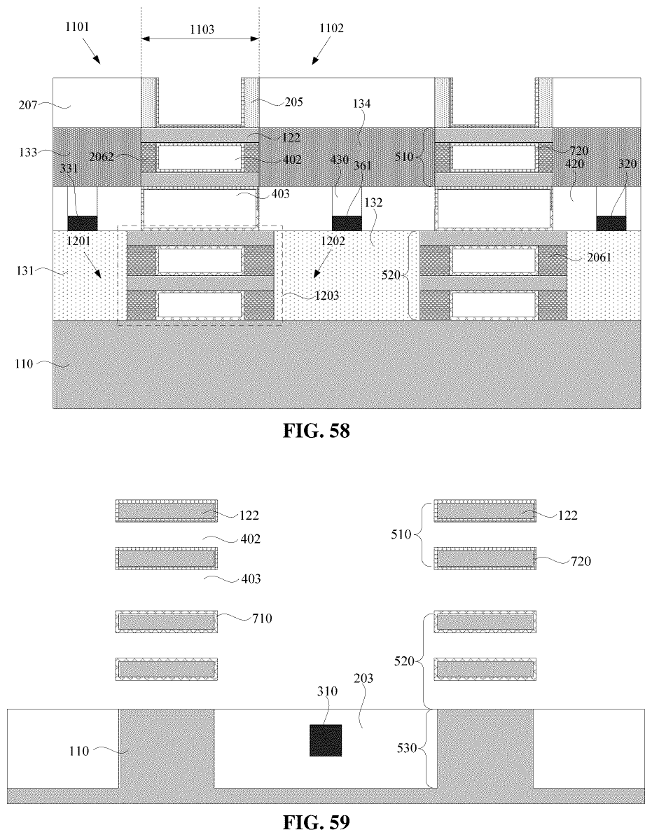

In step S1075, the protective layer 730 is removed, as shown in FIGS. 58 and 59.

In an embodiment of the present disclosure, the protective layer 730 may be removed after the first-type work function layer 720 and the second-type work function layer 710 are formed.

In practice, the protective layer 730 may be removed first, and then the first-type work function layer 720 is formed in all the to-be-filled gaps 402. That is, firstly, the second-type work function layer 710 may be formed in the to-be-filled gap 402 in the bottom structure 520, and then the first-type work function layer 720 may be formed.

In an embodiment of the present disclosure, after nanosheet channel release is performed, the plurality of to-be-filled gaps 402 are provided between the plurality of second semiconductor layers 122. The plurality of to-be-filled gaps 402 may be filled with the gate 160, and the gate 160 surrounds the second semiconductor layers 122, to form a gate-all-round structure. In an embodiment, the gate 160 surrounds the first-type work function layer 720 and the second-type work function layer 710. A stack constituted by the plurality of the second semiconductor layers 122 forms the top channel structure and the bottom channel structure, that is, a nanosheet channel of the complementary field-effect transistor is formed, as shown in FIGS. 60 and 61.

In practice, in addition to forming the gate 160 in the to-be-filled gaps 402, the gate 160 also overlays space remained after removing the spacer layer 207 and the dummy gate 204. The gate 160 overlaying the spacer layer 207 may be chemically mechanically polished for planarization.

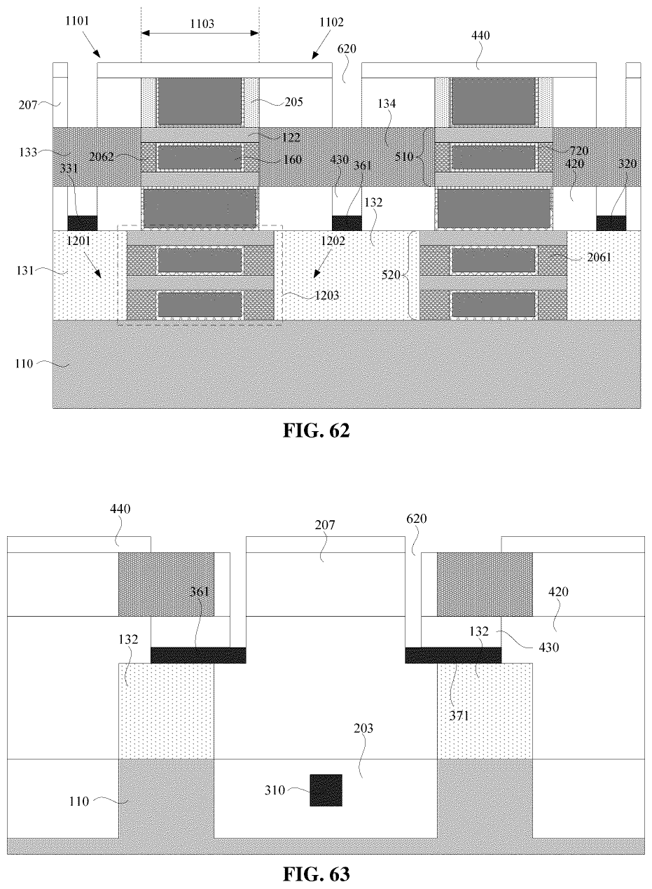

In step S108, a top ground connection layer, a top word line connection layer, a top bit line connection layer, a first storage top electrode and a second storage top electrode are respectively formed on the top source and the top drain, where the top ground connection layer is connected to the bottom ground connection layer, referring to FIG. 62 to FIG. 67.

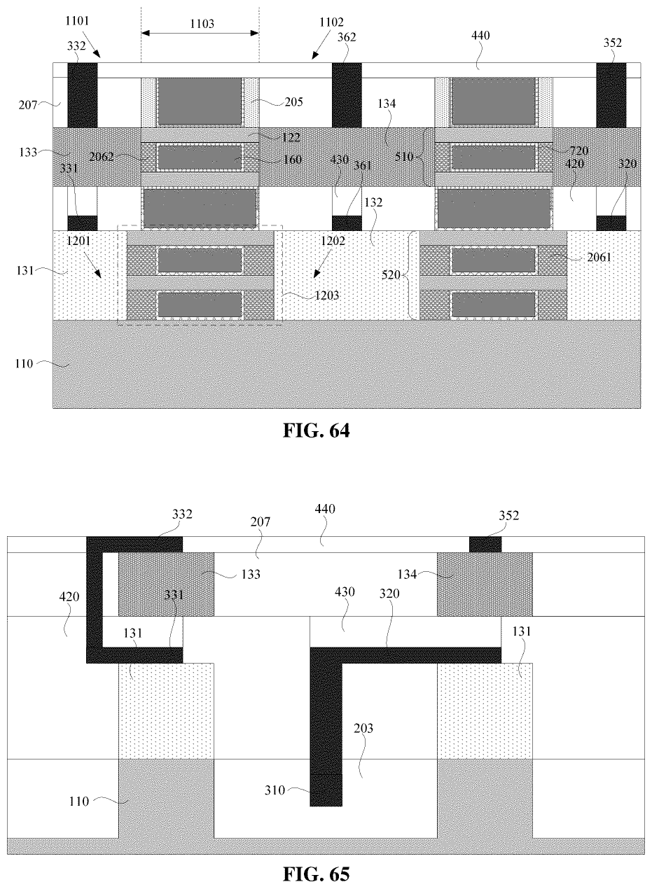

In an embodiment of the present disclosure, after the gate 160 is formed, a top ground connection layer 332, a top word line connection layer, a top bit line connection layer 352, a first storage top electrode 362 and a second storage top electrode 372 may be respectively formed on the top source 133 and the top drain 134, and the top ground connection layer 332 is connected to the bottom ground connection layer 331, as shown in FIGS. 64, 65, 66 and 67. The specific formation process is described in detail below.

In step S1081, a third dielectric layer 440 is formed on the top source 133 and the top drain 134.

In an embodiment of the present disclosure, after the top source 133 and the top drain 134 are formed, dielectric material may be deposited, and planarization may be performed, to form the third dielectric layer 440. The third dielectric layer 440 overlays the top source 133 and the top drain 134.

In step S1082, the third dielectric layer 440 on both sides of the top structure 510 is etched, to form a second groove 620, where the top source 133 and the top drain 134 are exposed by the second groove 620, as shown in FIGS. 62 and 63.

In an embodiment of the present disclosure, after the third dielectric layer 440 is formed, the third dielectric layer 440 on both sides of the top structure 510 may be etched to the top source 133 and the top drain 134, to form the second groove 620, where the top source 133 and the top drain 134 are exposed by the second groove 620, as shown in FIG. 62. The first storage bottom electrode 361 and the second storage bottom electrode 371 are also exposed by the second groove 620, as shown in FIG. 63.

In step S1083, the top ground connection layer 332, the top word line connection layer, the top bit line connection layer 352, the first storage top electrode 362 and the second storage top electrode 372 are respectively formed on the top source 133 and the top drain 134 exposed by the second groove 620, as shown in FIGS. 64, 65, 66 and 67.

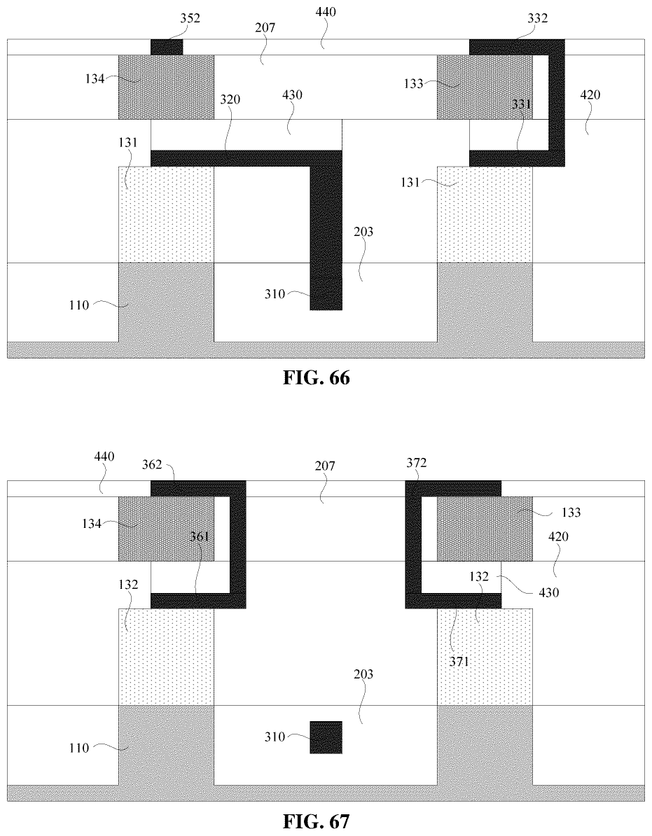

In an embodiment of the present disclosure, after the second groove 620 exposing the top source 133 and the top drain 134 is formed, the top ground connection layer 332, the first storage top electrode 362 and the top bit line connection layer 352 may be formed on the top source 133 and the top drain 134 exposed by the second groove 620, as shown in FIG. 64. The first storage top electrode 362 and the second storage top electrode 372 are formed on the top source 133 and the top drain 134 exposed by the second groove 620, as shown in FIG. 67. The top ground connection layer 332 and the top bit line connection layer 352 are formed on the top source 133 and the top drain 134 exposed by the second groove 620, and the top ground connection layer 332 is electrically connected to the bottom ground connection layer 331, as shown in FIGS. 65 and 66. In addition, the top word line connection layer is formed on the top source 133 and the top drain 134 exposed by the second groove 620.

In an embodiment of the present disclosure, a distance between a surface of the bottom ground connection layer 331 at a side closed to the substrate 110 and a surface of the bottom source 131 at a side away from the substrate 110 is less than a target threshold. That is, the bottom ground connection layer 331 is provided with a low depth. In an embodiment, the surface of the bottom ground connection layer 331 at a side closed to the substrate 110 may be flush with the surface of the bottom source 131 at a side away from the substrate 110.

The top ground connection layer 332 and the bottom ground connection layer 331 may be made of one or more of W, Al, Cu, Co, Ti, Ru, Sc, Pt, Ta and nitride.

In an embodiment of the present disclosure, the depth of the buried power line 310 ranges from 5 nm to 1000 nm, and the width of the buried power line 310 in the Y-Y ′direction ranges from 2 nm to 1000 nm.

In practice, the first storage electrode includes a first storage top electrode 362 and a first storage bottom electrode 361. The first storage electrode may be a Q storage electrode. The second storage electrode includes a second storage top electrode 372 and a second storage bottom electrode 371. The second storage electrode may be a QB storage electrode.

As can be seen from FIGS. 65 and 66, according to the embodiments of the present disclosure, no buried ground line is provided. in manufacturing a complementary field-effect transistor. Compared with a traditional technology of providing a buried ground line, the wiring space for grounding is reduced, and the length of a memory unit in the static random-access memory can be shortened from 76 nm to 66 nm, as illustrated in FIG. 68, thereby reducing the area of the memory unit. In addition, an etching process for high aspect ratio is not required, reducing a process requirement for high aspect ratio etching and filling metal materials. Moreover, since no buried ground line is provided, a distance between a power supply plane and a ground line plane is large, thus avoiding crosstalk and improving the performance of the manufactured complementary field-effect transistor. A specific value of area reduction of the memory unit shown in FIG. 68 is merely an example, and the actual extent of the area reduction in the present disclosure is not limited.

In addition to the method for manufacturing a complementary field-effect transistor according to the above embodiments, a complementary field-effect transistor is provided according to an embodiment of the present disclosure, and the operation principle thereof is described in detail below in conjunction with the drawings.

Reference is made to FIGS. 64, 65, 66 and 67, which are schematic cross-sectional diagrams of a complementary field-effect transistor according to an embodiment of the present disclosure.

The complementary field-effect transistor according to the present embodiment includes:
1 substrate 110;
a top source 133, a top drain 134, a top channel structure, a bottom source 131, a bottom drain 132 and a bottom channel structure disposed on a side of the substrate 110, where in a direction perpendicular to a plane where the substrate 110 is located, the top source 133 and the bottom source 131 overlap with each other, the top drain 134 and the bottom drain 132 overlap with each other, and the top channel structure and the bottom channel structure overlap with each other, where the top channel structure is located between the top source 133 and the top drain 134, the bottom channel structure is located between the bottom source 131 and the bottom drain 132, and the top channel structure and the bottom channel structure each includes a stack formed by a plurality of nanosheets;
a gate 160, where the gate 160 surrounds the plurality of nanosheets; and
a top ground connection layer 332 in contact with the top source 133, and a bottom ground connection layer 331 in contact with the bottom source 131, where the top ground connection layer 332 is connected to the bottom ground connection layer 331,
where a distance between a surface of the bottom ground connection layer 331 at a side closed to the substrate 110 and a surface of the bottom source 131 at a side away from the substrate 110 is less than a target threshold.

In a possible implementation, the surface of the bottom ground connection layer 331 at a side closed to the substrate 110 is flush with the surface of the bottom source 131 at a side away from the substrate 110.

In a possible implementation, the complementary field-effect transistor further includes a buried power line 310, where a depth of the buried power line 310 ranges from 5 nm to 1000 nm.

In a possible implementation, the top ground connection layer 332 and the bottom ground connection layer 331 are made of one or more of W, Al, Cu, Co, Ti, Ru, Sc, Pt, Ta and nitride.

Based on the complementary field-effect transistor provided based on the above embodiments, a static random-access memory is further provided according to an embodiment of the present disclosure. The static random-access memory includes a plurality of memory units, where the plurality of memory units each includes the complementary field-effect transistor according to any of the above embodiments.

In addition to the SRAM unit according to the above embodiments, a method for manufacturing an SRAM unit is further provided according to an embodiment of the present disclosure, and the operation principle thereof is described in detail below in conjunction with the drawings.

Reference is made to FIG. 69, which is a schematic flowchart of a method for manufacturing an SRAM unit according to an embodiment of the present disclosure.

In step S1001, a substrate is provided.

In step S1002, a first complementary field-effect transistor (CFET) and a third CFET are formed on the substrate in a first direction, and a fourth CFET and a second CFET are formed on the substrate in a second direction, where the first CFET, the second CFET, the third CFET and the fourth CFET each includes an upper transistor and a lower transistor, a conductivity type of the upper transistor is N-type, a conductivity type of the lower transistor is P-type, and the first direction and the second direction are parallel to each other.

In an embodiment of the present disclosure, a substrate 110 may be a semiconductor substrate, such as a bulk silicon substrate, and the substrate 110 may be doped to obtain a P-type semiconductor substrate or an N-type semiconductor substrate, such as a P-type silicon substrate or an N-type silicon substrate.

The first complementary field-effect transistor (CFET) and the third CFET may be formed on the substrate 110 in the first direction, and the fourth CFET and the second CFET may be formed on the substrate 110 in the second direction. The first CFET, the second CFET, the third CFET and the fourth CFET each includes an upper transistor and a lower transistor. A conductivity type of the upper transistor is N-type, and a conductivity type of the lower transistor is P-type. The first direction and the second direction are parallel to each other.

In an embodiment of the present disclosure, only one buried power line 310 is formed in the substrate 110 between the first direction and the second direction.

Specific steps of S1002 are as follows.

Stacked structures formed by alternately stacking first semiconductor layers 121 and second semiconductor layers 122 may be formed on a side of the substrate 110, referring to FIGS. 9 and 10.

The stacked structures are etched in the first direction and the second direction, to form fin structures, referring to FIGS. 11, 12, 13 and 14. For the specific steps of forming the fin structure, reference is made to step S102 in the above embodiment.

After the buried power line 310 is formed, the lower transistor is formed based on the fin structures. For the specific steps of forming a channel structure and a spacer in the lower transistor, reference is made to step S103 and step S104 in the above embodiments.

The upper transistor is formed based on the fin structures. For the specific steps of forming a channel structure and a spacer in the upper transistor, reference is made to step S106 and step S107 in the above embodiments.

In an embodiment of the present disclosure, the step, in which only one buried power line 310 is formed in the substrate 110 between the first direction and the second direction, includes: an insulation layer 410 that overlays the fin structure is formed after forming the fin structure, the insulation layer 410 between two fin structures is etched, to form a recess, and the buried power line 310 is formed in the recess.

Referring to step S1023 in the above embodiment, the buried power line 310 may be formed on the substrate 110 between the two fin structures. In an embodiment, dielectric insulating material is deposited, and then planarization, such as a chemical mechanical planarization (CMP) process, is performed, to form the insulation layer 410, referring to FIGS. 15 and 16. The insulation layer 410 between the two fin structures is etched to a depth of an area where the substrate structure 530 is located, to form a recess, referring to FIGS. 17 and 18. The recess formed by etching is filled with metal material, such as tungsten (W), and then planarization and etchback are performed, to form the buried power line 310, referring to FIGS. 19 and 20. Finally, the dielectric insulating material is continued to be deposited, and then planarization is performed, to fill the recess, referring to FIGS. 21 and 22.

In an embodiment of the present disclosure, before forming the upper transistor based on the fin structures, a buried power connection layer 320 connected to bottom sources 131 of the lower transistors in the first CFET and the second CFET may be formed. The buried power connection layer 320 is electrically connected to the buried power line 310. For the specific steps of forming the buried power connection layer 320, reference is made to step S105 in the above embodiment.

In an embodiment of the present disclosure, before the forming the upper transistor based on the fin structures, a first storage bottom electrode 361 connected to a bottom drain 132 of the lower transistor in the first CFET is formed, a second storage bottom electrode 371 connected to a bottom drain 132 of the lower transistor in the second CFET is formed. For the specific steps of forming the first storage bottom electrode 361 and the second storage bottom electrode 371, reference is made to step S105 in the above embodiment.

After the upper transistor is formed based on the fin structures, a first storage top electrode 362 connected to a top drain 134 of the upper transistor in the first CFET and a top source 133 of the upper transistor in the third CFET may also be formed. The first storage bottom electrode 361 and the first storage top electrode 362 constitute a first storage electrode. A second storage top electrode 372 connected to a top drain 134 of the upper transistor in the second CFET and a top source 133 of the upper transistor in the fourth CFET is formed. The second storage bottom electrode 371 and the second storage top electrode 372 constitute a second storage electrode. For the specific steps of forming the first storage top electrode 362 and the second storage top electrode 372, reference is made to step S108 in the above embodiment.

In an embodiment of the present disclosure, after the upper transistor is formed based on the fin structures, a third dielectric layer 440 may also be formed on the substrate. The third dielectric layer 440 is etched to form a second groove 620. A ground connection layer and a top ground connection layer 332 connected to top sources 133 of the upper transistors in the first CFET and the second CFET are formed in the second groove 620. The ground connection layer connects the top ground connection layer 332 and the bottom ground connection layer 331. That is, the top sources 133 of the upper transistors in the first CFET and the second CFET are grounded. For the specific steps of forming the top ground connection layer 332, reference is made to step S108 in the above embodiment.

The embodiments in this specification are described in a progressive manner, the same or similar parts between the embodiments may be referred to each other, and each embodiment focuses on the differences from other embodiments. In particular, since the method embodiment is basically similar to the structural embodiment, the description thereof is relatively concise, and for relevant parts reference may be made to the part in description of the structural embodiment. The structural embodiment described above is only illustrative, and those of ordinary skill in the art may understand and implement it without any creative effort.

The above are only preferred implementations of the present disclosure. Although the present disclosure is disclosed by referring to preferred embodiments, it is not intended to limit the present disclosure. Numerous modifications, variations and equivalent alternatives can be made by those skilled in the art based on the above disclosed method and technical contents without departing from the scope of the technical solutions. Therefore, any simple amendment, equivalent change or modification made to the above embodiments based on the technical essence of the present disclosure without departing from the content of the technical solutions of the present disclosure still falls within the protection scope of the technical solutions of the present disclosure.

1. A static random-access memory (SRAM) unit, comprising:
a substrate; and
a first complementary field-effect transistor (CFET), a second CFET, a third CFET and a fourth CFET located on the substrate,
wherein the first CFET, the second CFET, the third CFET and the fourth CFET each comprises an upper transistor and a lower transistor, a conduction type of the upper transistor is N-type, a conduction type of the lower transistor is P-type, and the upper transistors of the third CFET and the fourth CFET serve as gate transistors; and
wherein in the SRAM unit, only one buried power line is comprised in the substrate.

2. The SRAM unit according to claim 1, wherein the one buried power line is connected to a power supply.

3. The SRAM unit according to claim 1, wherein a depth of the buried power line ranges from 5 nm to 1000 nm.

4. The SRAM unit according to claim 1, wherein the first CFET, the second CFET, the third CFET and the fourth CFET each comprises:
a top source, a top drain, a top channel structure, a bottom source, a bottom drain and a bottom channel structure disposed on a side of the substrate, wherein in a direction perpendicular to a plane where the substrate is located, the top source and the bottom source overlap with each other, the top drain and the bottom drain overlap with each other, and the top channel structure and the bottom channel structure overlap with each other, wherein the top channel structure is located between the top source and the top drain, the bottom channel structure is located between the bottom source and the bottom drain, and the top channel structure and the bottom channel structure each comprises a stack formed by a plurality of nanosheets; and
a gate, wherein the gate surrounds the plurality of nanosheets.

5. The SRAM unit according to claim 4, wherein the buried power line is provided parallel to channel directions of the top channel structure and the bottom channel structure.

6. The SRAM unit according to claim 5, wherein channel directions of the first CFET and the third CFET are aligned along a straight line, and channel directions of the second CFET and the fourth CFET are aligned along another straight line.

7. The SRAM unit according to claim 4, wherein the first CFET and the second CFET each further comprises a top ground connection layer and a bottom ground connection layer,
wherein the top ground connection layer is in contact with the top source, the bottom ground connection layer is in contact with the bottom source, and the top ground connection layer is connected to the bottom ground connection layer.

8. A method for manufacturing a static random-access memory (SRAM) unit, comprising:
providing a substrate;
forming a first complementary field-effect transistor (CFET) and a third CFET on the substrate in a first direction, and forming a fourth CFET and a second CFET on the substrate in a second direction, wherein the first CFET, the second CFET, the third CFET and the fourth CFET each comprises an upper transistor and a lower transistor, a conductivity type of the upper transistor is N-type, a conductivity type of the lower transistor is P-type, and the first direction and the second direction are parallel to each other; and
forming only one buried power line in the substrate between the first direction and the second direction.

9. The method according to claim 8, wherein the forming a first CFET and a third CFET on the substrate in a first direction, and forming a fourth CFET and a second CFET on the substrate in a second direction, comprises:
forming a plurality of stacked structures formed by alternately stacking first semiconductor layers and second semiconductor layers on a side of the substrate, wherein in a direction perpendicular to a plane where the substrate is located, the stacked structures comprise a buffer layer located at a middle region;
etching the stacked structures in the first direction and the second direction, to form fin structures;
forming, after the buried power line is formed, the lower transistor based on the fin structures; and
forming the upper transistor based on the fin structures.

10. The method according to claim 9, wherein the forming only one buried power line in the substrate between the first direction and the second direction, comprises:
forming an insulation layer that overlays the fin structures, and etching the insulation layer between two fin structures, to form a recess; and
forming the buried power line in the recess.

11. The method according to claim 9, wherein before the forming the upper transistor based on the fin structures, the method further comprises:
forming a buried power connection layer connected to bottom sources of the lower transistors in the first CFET and the second CFET, wherein the buried power connection layer is connected to the buried power line.

12. The method according to claim 9, wherein before the forming the upper transistor based on the fin structures, the method further comprises:
forming a first storage bottom electrode connected to a bottom drain of the lower transistor in the first CFET, and forming a second storage bottom electrode connected to a bottom drain of the lower transistor in the second CFET,
wherein after the forming the upper transistor based on the fin structures, the method further comprises:
forming a first storage top electrode connected to a top drain of the upper transistor in the first CFET and a top source of the upper transistor in the third CFET, wherein the first storage bottom electrode and the first storage top electrode constitute a first storage electrode; and
forming a second storage top electrode connected to a top drain of the upper transistor in the second CFET and a top source of the upper transistor in the fourth CFET, wherein the second storage bottom electrode and the second storage top electrode constitute a second storage electrode.

13. The method according to claim 9, wherein after the forming the upper transistor based on the fin structures, the method further comprises:
forming a third dielectric layer on the substrate; and
etching the third dielectric layer to form a second groove, wherein a top ground connection layer connected to top sources of the upper transistors in the first CFET and the second CFET is formed in the second groove.

14. A complementary field-effect transistor, comprising:
a substrate;
a top source, a top drain, a top channel structure, a bottom source, a bottom drain and a bottom channel structure disposed on a side of the substrate, wherein in a direction perpendicular to a plane where the substrate is located, the top source and the bottom source overlap with each other, the top drain and the bottom drain overlap with each other, and the top channel structure and the bottom channel structure overlap with each other, wherein the top channel structure is located between the top source and the top drain, the bottom channel structure is located between the bottom source and the bottom drain, and the top channel structure and the bottom channel structure each comprises a stack formed by a plurality of nanosheets; and
a gate, wherein the gate surrounds the plurality of nanosheets; and
a top ground connection layer in contact with the top source, and a bottom ground connection layer in contact with the bottom source, wherein the top ground connection layer is connected to the bottom ground connection layer,
wherein a distance between a surface of the bottom ground connection layer at a side closed to the substrate and a surface of the bottom source at a side away from the substrate is less than a target threshold.

15. The complementary field-effect transistor according to claim 14, wherein the surface of the bottom ground connection layer at the side closed to the substrate is flush with the surface of the bottom source at the side away from the substrate.

16. The complementary field-effect transistor according to claim 14, further comprising a buried power line, wherein a depth of the buried power line ranges from 5 nm to 1000 nm.

17. The complementary field-effect transistor according to claim 15, wherein the top ground connection layer and the bottom ground connection layer are made of one or more of W, Al, Cu, Co, Ti, Ru, Sc, Pt, Ta and nitride.

18. A static random-access memory, comprising a plurality of memory units, wherein the plurality of memory units each comprises the complementary field-effect transistor according to claim 14.
